(19) United States
(12) Patent Application Publication
(10) Pub. No.: US 2026/0140142 A1
(43) Pub. Date: May 21, 2026

(54) METAL MOLDED PRODUCT

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG

(73) Assignee: POINT ENGINEERING CO., LTD., Chungcheongnam-do (KR)

(21) Appl. No.: 18/992,994

(22) PCT Filed: Jul. 6, 2023
(86) PCT No.: PCT/KR2023/009537

§ 371 Date: Nov. 20, 2025

(30) Foreign Application Priority Data
Jul. 13, 2022 (KR) 10-2022-0086142

(51) Int. Cl. G01R 1/067; G01R 1/04; G01R 3/00

(52) U.S. Cl. CPC G01R 1/06733; G01R 1/0491; G01R 1/06755; G01R 3/00

(57) ABSTRACT

Proposed is an electroconductive contact pin, and the objective is to manufacture a metal molded product with a high aspect ratio, the metal molded product using a mold made of an anodized film material so that deformation of the electroconductive contact pin is prevented, and being capable of effectively improving current carrying capacity.

### CROSS-REFERENCES

This application is a 371 of international application of PCT application serial no. PCT/KR 2023/009537, filed on Jul. 6, 2023, which claims the priority benefit of Korea application no. 10-2022-0086142, filed on Jul. 13, 2022. The entirety of each of the above mentioned patent applications is hereby incorporated by reference herein and made a part of this specification.

### TECHNICAL FIELD

The present disclosure relates to a metal molded product.

### DESCRIPTION OF RELATED ART

Metal molded products can be manufactured by an MEMS technology and a plating technology and their applications may vary depending on their intended use.

Metal molded products can be manufactured using an MEMS process. To observe the process of manufacturing metal formed products using N MEMS process, first, a photoresist film is applied to the surface of a conductive substrate and then the photoresist film is patterned. Thereafter, a metal material is deposited on the exposed surface of the conductive substrate in an opening through an electroplating method using the photoresist film as a mold and then the photoresist film and the conductive substrate are removed, thereby obtaining a metal molded product. The shape of the metal molded product manufactured through this process has the same shape as the opening formed in the photoresist film mold. In this case, the thickness of the metal molded product is affected by the height of the photoresist film mold.

When a photoresist film is used as a mold in an electroplating method, it is difficult to secure a sufficiently large height of the photoresist film mold. Accordingly, it is also not possible to secure a sufficiently large thickness of metal molded products. Metal molded products need to be manufactured with a thickness over a predetermined level in consideration of electrical conductivity, resilience, brittle fracture, etc. In order to increase the thickness of metal molded products, a mold formed by stacking photoresist films in multiple layers can be considered. However, in this case, slight steps are formed between the layers of photoresist film, so there is a problem that the sides of metal molded products are not vertically formed and slight stepped regions remain. Further, when photoresist films are stacked in multiple layers, there is a problem that it is difficult to precisely reproduce the shape of metal molded products with dimensional ranges of less than several tens of μm.

When metal molded products are manufactured using existing photoresist film molds, as described above, there is a limitation in manufacturing metal molded products with a high aspect ratio.

A metal molded product, as an example, may be an electroconductive contact pin for testing test objects.

An electrical characteristic test of semiconductor devices is performed by bringing a test object (a semiconductor wafer or a semiconductor package) close to a testing apparatus having multiple electroconductive contact pins and bringing the electroconductive contact pins into contact with a corresponding external terminal (solder balls or bumps), etc. of the test object. As an example of testing apparatuses, a probe card or a test socket is included, but they are not limited thereto.

The electroconductive contact pins functions as an intermediate mediator enabling exchange of test signals between the testing apparatus and individual tests. However, since the aspect ratios of electroconductive contact pins of the related art are small, they often have a problem of bending or warping in the horizontal direction as their body becomes convex due to pressure applied to both ends. Further, since the aspect ratios are small, the content of metals with high electrical conductivity is low during multilayer plating, so there is a limitation in improving the current carrying capacity (CCC).

### RELATED ART DOCUMENT

### Patent Document

(Patent Document 1) Korean Patent Application Publication No. 10-2018-0004753

### SUMMARY OF THE INVENTION

### Technical Problem

The present disclosure has been made in an effort to solve the problems of the related art described above and an objective of the present disclosure is to provide a metal molded product in which at least any one of the distance d of a gap, the distance t of a line width, and the radius r of an open hole has a high aspect ratio.

### Technical Solution

In order to achieve the objectives described above, a metal molded product according to the present disclosure is a metal molded product manufactured using a mold made of an anodized film material, wherein the metal molded product has a total length dimension (L) in a longitudinal direction (±y direction), has a total thickness dimension (H) in a thickness direction (±z direction) perpendicular to the longitudinal direction, and has a total width dimension (W) in a width direction (±x direction) perpendicular to the longitudinal direction, a gap is formed between two portions spaced apart and opposite each other, and, based on a gap with a smallest distance among the gaps, an aspect ratio (H:d) of the total thickness dimension (H) and a distance (d) of the gaps has a range of 13:1 or more and 80:1 or less.

Meanwhile, a metal molded product according to the present disclosure is a metal molded product manufactured using a mold made of an anodized film material, wherein the metal molded product has a total length dimension (L) in a longitudinal direction (±y direction), has a total thickness dimension (H) in a thickness direction (±z direction) perpendicular to the longitudinal direction, and has a total width dimension (W) in a width direction (±x direction) perpendicular to the longitudinal direction, the metal molded product has line widths, and, based on a smallest line width among the line widths, an aspect ratio (H:t) of the total thickness dimension (H) and a distance (t) of the line widths has a range of 13:1 or more and 80:1 or less.

Meanwhile, a metal molded product according to the present disclosure is a metal molded product manufactured using a mold made of an anodized film material, wherein the metal molded product has a total length dimension (L) in a longitudinal direction (±y direction), has a total thickness dimension (H) in a thickness direction (±z direction) perpendicular to the longitudinal direction, and has a total width dimension (W) in a width direction (±x direction) perpendicular to the longitudinal direction, the metal molded product has intersections where two portions intersect in an x-y plane, the interest has an open hole, and, based on an open hole with a smallest radius among the open holes, an aspect ratio (H:r) of the total thickness dimension (H) and a radius (r) of the open holes has a range of 26:1 or more and 160:1 or less.

Further, the total thickness dimension is 80 μm or more and 160 μm or less.

Further, the distance of the gap with the smallest distance among the gaps is 2 μm or more and 6 μm or less.

Further, a distance of the line width with the smallest distance among the line widths is 2 μm or more and 6 μm or less.

Further, the radius of the open hole with the smallest radius among the open holes is 1 μm or more and 3 μm or less.

Further, any one of the two portions spaced apart and opposite each other is a portion that slides in one direction.

Further, the metal molded product includes a supporting frame and a body being separable from the supporting frame, and a distance of a line width of a cutting portion at which the supporting frame and the body are connected is 2 μm or more and 6 μm or less.

Further, the metal molded product has a plurality of metal layers stacked in the thickness direction of the metal molded product.

Further, the metal molded product is an electroconductive pin provided between a test object and a circuit board.

### Advantageous Effects

The present disclosure provides a metal molded product in which at least any one of the distance (d) of a gap, the distance (t) of a line width, and the radius ® of an open hole has a high aspect ratio.

### BRIEF DESCRIPTION OF DRAWINGS

FIG. 1a is a plan view of a metal molded product according to a first preferred embodiment of the present disclosure and FIG. 1b is a perspective view of the metal molded product according to the first preferred embodiment of the present disclosure.

FIG. 2 is a view showing FIG. 1a together with an enlarged view of a portion of FIG. 1a.

FIG. 3a and FIG. 3b are views showing a manufacturing method of the metal molded product according to the first preferred embodiment of the present disclosure, in which FIG. 3a is a view showing an anodized film mold and FIG. 3b is a cross-sectional view of line A-A′ in FIG. 3a.

FIG. 4a and FIG. 4b are views showing a manufacturing method of the metal molded product according to the first preferred embodiment of the present disclosure, in which FIG. 4a is a view showing a process of the metal molded product by performing plating using an anodized film mold and FIG. 4b is a cross-sectional view of line A-A′ in FIG. 4a.

FIG. 5 is a plan view showing the state before a body is separated from a supporting frame after the anodized film mold is removed.

FIG. 6a is a plan view of a metal molded product according to a second preferred embodiment of the present disclosure and FIG. 6b is a perspective view of the metal molded product according to the second preferred embodiment of the present disclosure.

FIG. 7 is a view showing FIG. 6a together with an enlarged view of a portion of FIG. 6a.

FIG. 8a is a plan view of a metal molded product according to a third preferred embodiment of the present disclosure and FIG. 8b is a perspective view of the metal molded product according to the third preferred embodiment of the present disclosure.

FIG. 9 is a view showing FIG. 8a together with an enlarged view of a portion of FIG. 8a.

FIG. 10a is a plan view of a metal molded product according to a fourth preferred embodiment of the present disclosure and FIG. 10b is a perspective view of the metal molded product according to the second preferred embodiment of the present disclosure.

FIG. 11 and FIG. 12 are views showing FIG. 10a together with an enlarged view of a portion of FIG. 10a.

### DESCRIPTION OF THE INVENTION

The followings provide only the principle of the present disclosure. Accordingly, those skilled in the art may implement the principle of the present disclosure and achieve various apparatuses included in the concept and range of the present disclosure which are not clearly described or shown herein though. Further, all conditional terminologies and embodiments described herein should be understood as being definitely intended as an object for understanding the concept of the present disclosure without limiting the specifically stated embodiments and states.

The objectives, features, and advantages of the present disclosure described above will be clearer through the following detailed description relating to the accompanying drawing, so the spirit of the present disclosure would be easily implemented by those skilled in the art.

Embodiments described in the specification will be explained with reference to cross-sectional views and/or perspective views that are ideal exemplary views of the present disclosure. The thicknesses, etc. of films and regions shown in the drawings are exaggerated for effective description of the present disclosure. The shapes of the exemplary views may be deformed by manufacturing technologies and/or tolerances. Further, the number of molded products shown in the drawings is shown only partially as an example. Accordingly, embodiments of the present disclosure are not limited to the specific types shown in the drawings and include variation of the types, depending on the manufacturing processes.

A metal molded product according to a preferred embodiment of the present disclosure refers to an object made of a metal material having predetermined thickness, height, and length. A metal molded product according to a preferred embodiment of the present disclosure can be manufactured by an MEMS technology and a plating technology and their applications may vary depending on their intended use.

A metal molded product according to a preferred embodiment of the present disclosure may be an electroconductive contact pin for testing test objects. Metal molded products are mounted on testing apparatuses and used to transmit electrical signals in electrical and physical contact with test objects. The testing apparatuses may be testing apparatuses that are used in the manufacturing process of semiconductors, and for example, may be a probe card or a test socket, depending on test objects. A testing apparatus according to a preferred embodiment of the present disclosure is not limited thereto and includes any kinds of apparatus as long as they are used to check whether test objects are defective by applying electricity.

In the following description, the width direction of a metal molded product is the ±x direction in the drawings, the longitudinal direction of the metal molded product is the ty in the drawings, and the thickness direction of the metal molded product is the ±z. A metal molded product has a total length dimension L in the longitudinal direction (±y direction), has a total thickness dimension H in the thickness direction (±z direction) perpendicular to the longitudinal direction, and has a total width dimension W in the width direction (±x direction) perpendicular to the longitudinal direction.

Unlike the related art, since an anodized film mold is used, the total thickness dimension H of a metal molded product can have a range of 80 μm or more and 160 μm or less. Further, since an anodized film with high rigidity remains as a wall when an internal space is formed in the anodized film mold, it is possible to manufacture a metal molded product having a gap d, a line width t, and a radius r of an open hole with a high aspect ratio.

A photoresist mold using a photoresist is manufactured by repeatedly spraying and solidifying a photosensitive solution that is a liquid component, so layers are formed in 30 μm increments. Even after plating is completed, nodes like those of bamboo are formed at points where the layer change, so deformation is made easy. There is a limit to stack a mold high and precise patterning is also difficult. Accordingly, when an existing photoresist is used, it is difficult for metal molded products to have a total thickness dimension H of 60 μm or more. However, when a mold made of an anodized film material is used in accordance with a preferred embodiment of the present disclosure, this problem is solved. First, since an anodized film that is already in a solid state is etched to form an internal space, precise patterning is possible. Further, it is possible to form a mold without layers while having a total thickness dimension H between 80 μm or more and 160 μm or less, which has the characteristic of being solid. Accordingly, the completed metal molded product has no node, unlike using a photoresist mold, so it does not deform even after being used. The metal molded product according to a preferred embodiment of the present disclosure exhibits an effect that it is possible to achieve a shape with a high aspect ratio, which was limited in implementation by a photoresist mold using a photoresist, in that, as described above, the metal molded product is manufactured using an anodized mold using an anodized film.

The metal molded product according to a preferred embodiment of the present disclosure has a gap formed between two portions spaced apart and opposite each other. Any one of the two portions spaced apart and opposite each other may be a portion that slides in one direction. Based on the gap with the smallest distance among several gaps formed by two portions opposite to each other, the aspect ratio H:d of the total thickness dimension H and the distance d of the gaps has a range of 13:1 or more and 80:1 or less. In this case, the distance d of the gap with the smallest distance among the gaps may be 2 μm or more and 6 μm or less. Accordingly, the metal molded product can have a gap with a high aspect ratio.

Further, the metal molded product has line widths and the aspect ratio H:t of the total thickness dimension H and the distance t of the line widths has a range from 13:1 or more and 80:1 or less, based on the smallest line width. In this case, the distance t of the line width with the smallest distance among the line widths may be 2 μm or more and 6 μm or less. Accordingly, the metal molded product can have a line width with a high aspect ratio.

Further, the metal molded product has intersections where two portions intersect in the x-y plane, an intersection has an open hole, and, based on the open hole with the smallest radius among the open holes, the aspect ratio H:r of the total thickness dimension H and the radius r of the open holes has a range of 26:1 or more and 160:1 or less. In this case, the radius r of the open hole with the smallest radius among the open holes may be 1 μm or more and 3 μm or less. Accordingly, the metal molded product can have an open hole with a high aspect ratio.

Meanwhile, the total length L of a metal molded product should be small to effectively respond to a high-frequency characteristic test of test objects. Accordingly, the length of an elastic portion should be small. However, when the length of the elastic portion is small, there is a problem of an increase of contact pressure. In order to make the length of the elastic portion small and prevent an increase of contact pressure, the distance t of line width of a plate constituting the elastic portion should be made small. However, when the distance t of line width of a flat plate constituting the elastic portion is made small, there is a problem that the elastic portion is easily damaged. In order to prevent an increase of contact pressure and prevent damage to the elastic portion while making the length of the elastic portion small, the total thickness dimension H of the flat plate constituting the elastic portion should be made large.

The metal molded product according to a preferred embodiment of the present disclosure is formed such that the distance t of line width of a flat plate is small and the total thickness dimension H of the flat plate is large. That is, the ratio of the total thickness dimension H to the distance t of line width of the flat plate becomes large, so the elastic portion has a line width with a high aspect ratio. Preferably, the distance t of line width of the flat plate constituting the elastic portion can be in the range of 2 μm or more and 15 μm or less, the total thickness dimension H can be in the range of 80 μm or more and 160 μm or less, and the ratio of the distance t of line width and the total thickness dimension H of the flat plate can be in the range of 1:5 or more and 1:60 or less. For example, the distance t of line width of the flat plate may be substantially 4 μm and the total thickness dimension H may be 100 μm, whereby the ratio of the distance t of line width and the total thickness dimension H may be 1:25.

Accordingly, it is possible to make the length of the elastic portion small while preventing damage to the elastic portion, and even though the length of the elastic portion is made small, appropriate contact pressure can be achieved. Further, it is possible to increase the total thickness dimension H relative to the substantial width t of the flat plate constituting the elastic portion, so the resistance to the moment acting in the forward and backward direction of the elastic portion increases, and as a result, the contact stability is improved. As described above, since it is possible to make the total length dimension L of the metal molded product small, it is easy to respond to the high-frequency characteristic, and the elastic restoration time of the elastic portion decreases, so it is possible to achieve the effect of reducing the test time as well. Further, since the line width t of the flat plate constituting the metal molded product is smaller than the thickness H, the bending resistance in the forward and backward directions is enhanced.

Further, since the total thickness dimension H of the metal molded product is determined in the range of 80 μm or more and 160 μm or less, the current carrying capacity can be improved. In other words, when the metal molded product is subjected to multi-layer plating with first and second metal layers, it becomes possible to increase the content of the second metal layer with high electrical conductivity, so it becomes possible to improve the current carrying capacity in comparison to metal molded products according to the related art.

Hereinafter, preferred embodiments of the present disclosure are described in detail with reference to the drawings. In the description of various embodiments, same names and same reference numerals are given to components having same functions for the convenience even though the embodiments are different. Further, configurations and operations described already in other embodiments are omitted for the convenience.

Metal molded product (100a) according to first embodiment

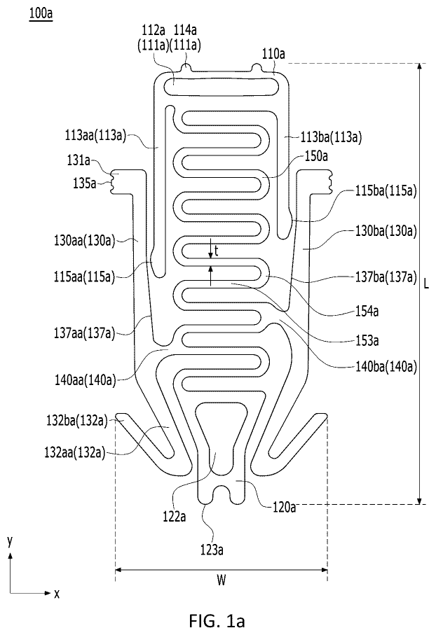

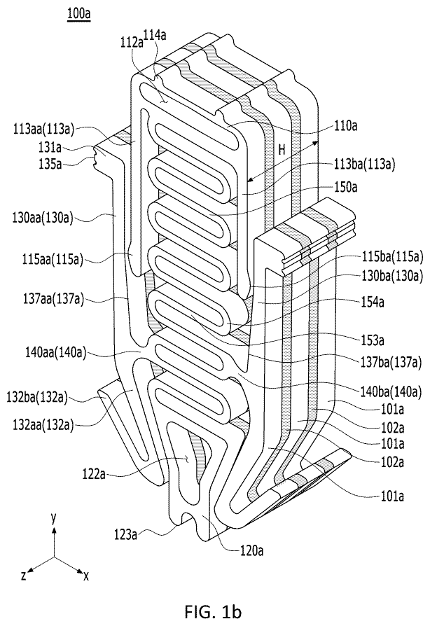

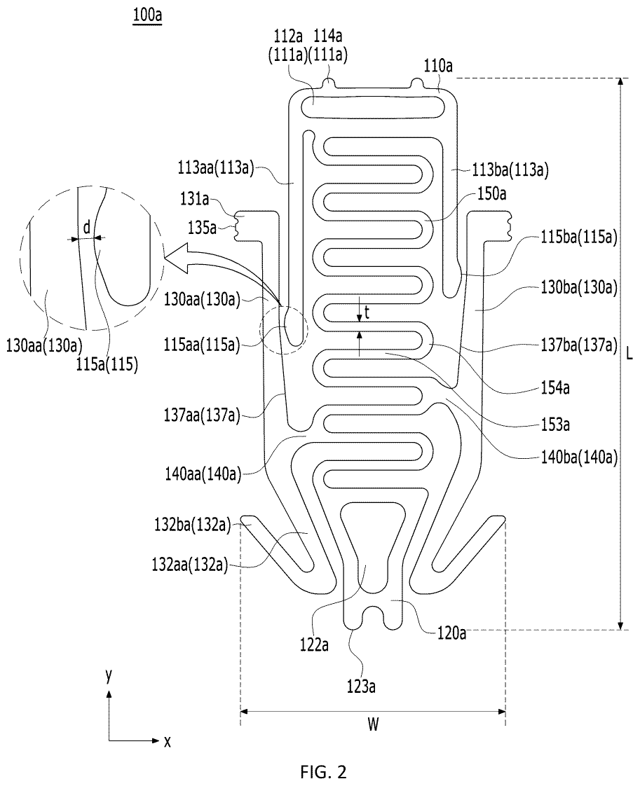

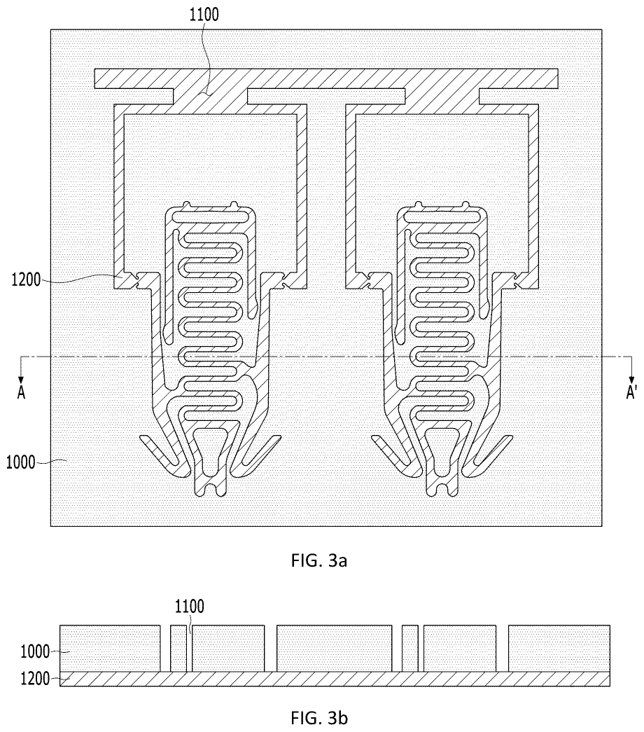

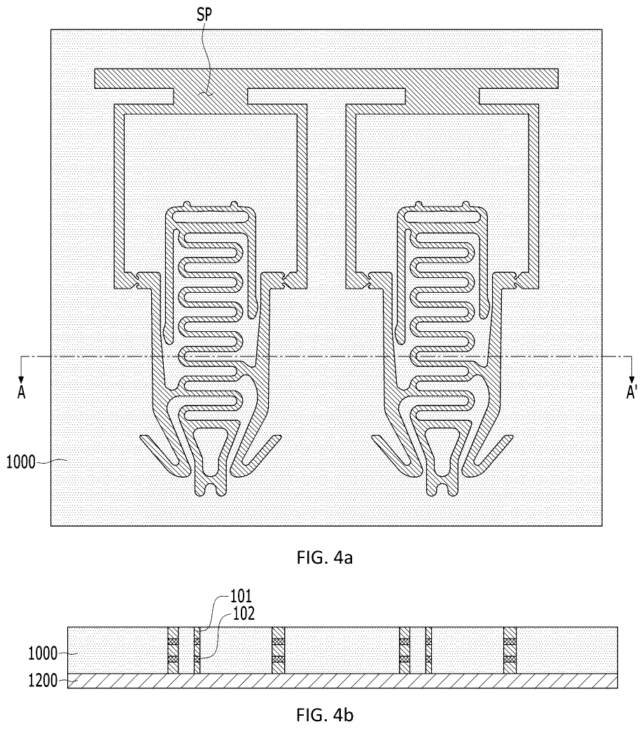

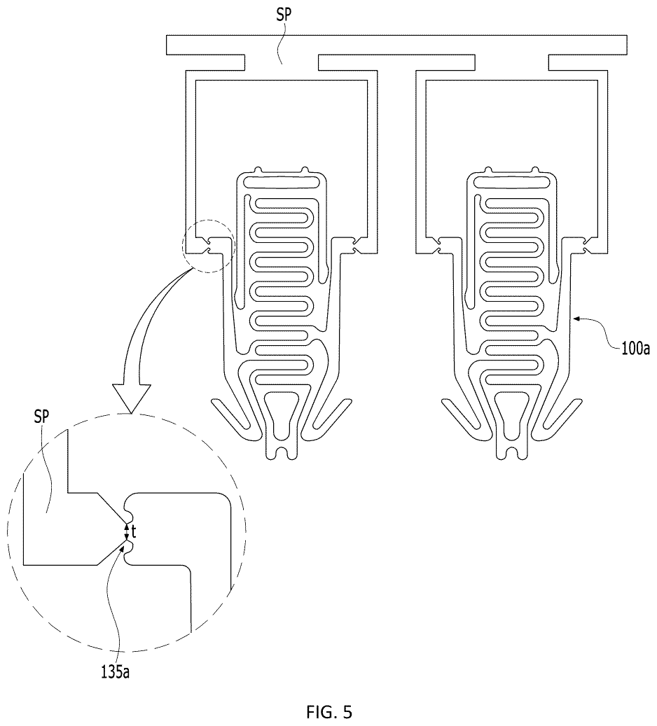

FIG. la is a plan view of a metal molded product 100a according to a first preferred embodiment of the present disclosure and FIG. 1b is a perspective view of the metal molded product 100a according to the first preferred embodiment of the present disclosure, FIG. 2 is a view showing FIG. la together with an enlarged view of a portion of FIG. 1a, FIG. 3a and FIG. 3b are views showing a manufacturing method of the metal molded product 100a according to the first preferred embodiment of the present disclosure, in which FIG. 3a is a view showing an anodized film mold 1000 and FIG. 3b is a cross-sectional view of line A-A′ in FIG. 3a, FIG. 4a and FIG. 4b are views showing a manufacturing method of the metal molded product 100a according to the first preferred embodiment of the present disclosure, in which FIG. 4a is a view showing a process of the metal molded product 100a by performing plating using the anodized film mold 1000 and FIG. 4b is a cross-sectional view of line A-A′ in FIG. 4a, and FIG. 5 is a plan view showing the state before a body is separated from a supporting frame SP after the anodized film mold 100 is removed.

The metal molded product 100a includes a first connection portion 110a, a second connection portion 120a, a supporting portion 130a longitudinally extending, an elastic portion 150a connected to the first connection portion 110a and the second connection portion 120a and being able to longitudinally elastically deform, and a bridge 140a connecting the elastic portion 150a and the supporting portion 130a.

The first connection portion 110a, the second connection portion 120a, the supporting portion 130a, the bridge 140a, and the elastic portion 150a are integrally provided. The first connection portion 110a, the second connection portion 120a, the supporting portion 130a, the bridge 140a, and the elastic portion 150a are formed all at once using a plating process. The metal molded product 100a, as will be described below, is formed by filling an internal space 1100 with a metal material through electroplating using a mold 1000 having the internal space 1100, so the first connection portion 110a, the second connection portion 120a, the supporting portion 130a, the bridge 140a, and the elastic portion 150a are integrally formed such that they are connected to each other.

The shapes of cross-sections in the thickness direction (±z direction) of the metal molded product 100a are the same. In other words, the same shape in the x-y plane extends in the thickness direction (±z direction).

The metal molded product 100a has a plurality of metal layers stacked in the thickness direction (±z direction). The plurality of metal layers includes a first metal layer 101a and a second metal layer 102a.

The first metal layer 101a may be made of metal with high wear resistance relative to the second metal layer 102a, preferably, metal selected from rhodium (Rd), platinum (Pt), iridium (Ir), palladium (Pd), nickel (Ni), manganese (Mn), tungsten (W), phosphorus (P), or alloys thereof, or a palladium-cobalt (PdCo) alloy, a palladium-nickel (PdNi) alloy, a nickel-phosphorus (NiPh) alloy, a nickel-manganese (NiMn) alloy, a nickel-cobalt (NiCo) alloy, or a nickel-tungsten (NiW) alloy. The second metal layer 102a may be made of metal with high electrical conductivity relative to the first metal layer 101a, preferably, metal selected from copper (Cu), silver (Ag), gold (Au), or alloys thereof. However, the metal layers are not limited thereto.

The first metal layer 101a is provided on the bottom surface and the top surface of the metal molded product 100a in the thickness direction (±z direction), and the second metal layer 102a is provided between the first metal layers 101a. For example, in the metal molded product 100a, a first metal layer 101a, a second metal layer 102a, and a first metal layer 101a may be sequentially stacked in the thickness direction (±z direction), and the number of the layers that are stacked may be three or more.

The first connection portion 110a includes a contact portion 111a that comes into contact with a connection target (more preferably, test object), and a flange 113a extending downward from the contact portion 111a and covering at least a portion of the elastic portion 150a. When the elastic portion 150a elastically deforms, the contact portion 111a and the flange 113a are integrally operated.

The contact portion 111a is the portion that comes into contact with a connection terminal of a test object.

The contact portion 111a has a cavity 112a so that a contact surface can be more easily deformed by pressure applied by a test object. The upper surface of the contact portion 111a over the cavity 112a is the portion that comes into contact with a connection terminal of a test object and the lower surface of the contact portion 111a under the cavity 112a is connected to the elastic portion 150a. The cavity 122a is formed as an empty space with curved left and right sides, thereby allowing the upper surface of the contact portion 111a to more easily deform.

The contact portion 111a includes at least one or more projections 114a on the top surface thereof to achieve multi-contact with a connection terminal. The projection 114a protrudes and elongates to be longer than the surrounding portions in the thickness direction (±z direction) of the contact portion 111a.

The first connection portion 110a is connected to the elastic portion 130a, so it can be elastically vertically moved by contact pressure.

When a test object is tested, a connection terminal of the test object is moved downward in contact with the top surface of the first connection portion 110a. Accordingly, the elastic portion 150a connected with the first connection portion 110a is compressively deformed. As the first connection portion 110a is moved downward, the first connection portion 110a comes into contact with the supporting portion 130a.

The flange 113a of the first connection portion 110a extends downward from the contact portion 111a to cover at least a portion of the elastic portion 150a. In this configuration, the flange 113a continues from the width-directional end of the contact portion 111a and extends downward. As a result, the contact portion 111a does not protrude further than the flange 113a in the width direction (±x direction) and the flange 113a does not protrude further than the contact portion 111a upwardly in the longitudinal direction (+y direction).

The flange 113a extends downward (−y direction) from the contact portion 111a and at least a portion of the flange 113a is disposed between the elastic portion 150a and the supporting portion 130a.

When the elastic portion 150a is compressed, the flange 113a is moved down (−y direction) in the space between the elastic portion 150a and the supporting portion 130a. On the contrary, when the elastic portion 150a is restored, the flange 113a is moved upward (+y direction) in the space between the elastic portion 150a and the supporting portion 130a.

The supporting portion 130a includes a first supporting portion 130aa positioned on a side of the metal molded product 100a and a second supporting portion 130ba positioned on another side of the metal molded product 100a. Further, the flange 113a includes a first flange 113aa positioned at a side of the elastic portion 150a and a second flange 113ba positioned at another side of the elastic portion 150a opposite to the first flange 113aa. The first flange 113aa and the second flange 113ba are connected to the contact portion 111a.

In the width direction, at least a portion of the first flange 113aa is positioned between the first supporting portion 130aa and the elastic portion 150a and at least a portion of the second flange 113ba is positioned between the elastic portion 150a and the second supporting portion 130ba. When the elastic portion 150a is compressed, the first flange 113aa is moved downward (−y direction) in the space between the elastic portion 150a and the first supporting portion 130aa and the second flange 113ba is moved downward (−y direction) in the space between the elastic portion 150a and the second supporting portion 130ba. On the contrary, when the elastic portion 150a is restored, the first flange 113aa is moved upward (+y direction) in the space between the elastic portion 150a and the first supporting portion 130aa and the second flange 113ba is moved upward (+y direction) in the space between the elastic portion 150a and the second supporting portion 130ba.

The flange 113a of the first connection portion 110a is positioned to overlap the supporting portion 130a in the width direction. In detail, the flange 113a extends from the contact portion 111a such that at least a portion of the flange 113a is positioned in the space between the supporting portion 130a and the elastic portion 150a. When an eccentric pressing force is applied by a connection terminal 410 that is in contact with the first connection portion 110a and leftward tilting occurs, the second flange 113ba comes into contact with the second supporting portion 130ba, thereby preventing excessive buckling in the leftward direction. Further, when an eccentric pressing force is applied by a connection terminal 410 that is in contact with the first connection portion 110a and rightward tilting occurs, the first flange 113aa comes into contact with the first supporting portion 130aa, thereby preventing excessive buckling in the rightward direction. As described above, when an eccentric pressing force is applied, the flange 113a comes into contact with the supporting portion 130a, thereby preventing excessive buckling of the metal molded product 100a in the left and right directions.

A convex portion 115a protruding toward the supporting portion 130a is formed at the free end of the flange 113a. In response, the supporting portion 130a has an inner-surface inclined portion 137a that inclines inward while becoming thicker in width as it goes downward (−y direction). By the configuration of the convex portion 115a and the inner-surface inclined portion 137a, when the flange 113a is moved downward, the flange 113a smoothly comes into contact with the inner surface of the supporting portion 130a and additionally moves down while maintaining the contact state.

When the elastic portion 150a is not compressed, the flange 113a and the supporting portion 130a are spaced apart from each other. The gap between the flange 113a and the supporting portion 130a may be the smallest gap among several gaps. Further, the flange 113a is a portion that slides in one direction with respect to the supporting portion 130a. In this configuration, the distance d of the gap between the flange 113 a and the supporting portion 130 a may be 2 μm or more and 6 μm or less. The height of the gap may be 80 μm or more and 160 μm or less.

When the elastic portion 150a is compressed and the flange 113a is moved downward (−y direction), the flange 113a comes into contact with the inner surface of the supporting portion 130a, thereby forming a current path. In more detail, when the flange 113a is moved downward (−y direction), the convex portion 115a of the flange 113a comes into contact with the inner-surface inclined portion 137a of the supporting portion 130a, thereby forming a current path. The flange 113a and the supporting portion 130a are spaced apart from each other and do not interfering with deformation of the elastic portion 150a in the early stage of compression, and thereafter, the outer surface of the flange 113a and the inner surface of the supporting portion 130a generate friction resistance by coming into contact with each other, whereby excessive deformation of the elastic portion 150a is prevented, and, in testing, a current path is formed between the supporting portion 130a and the flange 113a.

The bridge 140a connects the elastic portion 150a and the supporting portion 130a to each other.

The bridge 140a includes a first bridge 140aa connecting the elastic portion 150a and the first supporting portion 130aa and a second bridge 140ba connecting the elastic portion 150a and the second supporting portion 130ba.

The first bridge 140aa connects the elastic portion 150a and the first supporting portion 130aa and the second bridge 140ba connects the elastic portion 150a and the second supporting portion 130ba.

The first bridge 140aa and the second bridge 140ba may be at the same positions or different positions in the longitudinal direction. According to a preferred embodiment of the present disclosure, the first bridge 140aa and the second bridge 140ba are provided at different positions in the longitudinal direction such that stress is distributed. With reference to FIG. 1a and FIG. 1b, the first bridge 140aa is provided to be closer to the second connection portion 120a than the second bridge 140ba and the second bridge 140ba is provided to be closer to the second connection portion 110a than the first bridge 140aa.

The bridge 140a prevents foreign substances that have come inside from above from moving to the second connection portion 120a and foreign substances that have come inside from under also from moving to the first connection portion 110a. By restricting movement of foreign substances that have come inside, it is possible to prevent interference with the operation of the first and second connection portions 110a and 120a by foreign substances.

When the flange 113a is moved downward, the free end of the flange 113a can come into contact with the bridge 140a. Accordingly, the bridge 140a can function as a stopper that restricts additional downward movement of the flange 113a.

The lengths of the first flange 113aa and the second flange 113ba may be different from each other. In more detail, the length of the first flange 113aa may be larger than the length of the second flange 113ba. This is based on the positions of the first bridge 140aa and the second bridge 140ba, and since the first bridge 140aa is positioned lower than the second bridge 140ba, the length of the first flange 113a is designed to be larger than the length of the second flange 113ba so that they can function as a stopper.

The top surface of the bridge 140a is formed concave and the free end of the flange 113a is formed convex to correspond to the shape of the top surface of the bridge 140a. The convex free end of the flange 113a is fitted into the concave portion of the bridge 140a, whereby it is possible to firmly support the descending position of the flange 113a that descends without wobbling.

The second connection portion 120a comes into contact with a connection target (more preferably, a pad of a circuit board).

The second connection portion 120a has a cavity 122a so that a contact surface can be more easily deformed by pressure applied by the pad of a circuit board.

Further, the second connection portion 120a has at least one or more projections 123a to achieve multi-contact with the pad.

The second connection portion 120a is connected to the elastic portion 130a, so it can be elastically vertically moved by contact pressure.

When the second connection portion 120a is pressed in contact with the pad of the circuit board, the elastic portion 150a is compressively deformed, whereby the second connection portion 120a is moved upward. When the second connection portion 120a is moved upward by a predetermined distance, the pad of the circuit board comes into contact with the supporting portion 130a as well. As a result, the pad of the circuit board comes into contact with both the second connection portion 120a and the supporting portion 130a, thereby forming a current path.

The first supporting portion 130aa and the second supporting portion 130ba are formed in the longitudinal direction of the metal molded product 100a, and the first supporting portion 130aa and the second supporting portion 130ba are integrally connected to the bridge 140a extending in the width direction of the metal molded product 100a. The first connection portion 110a is connected to the upper portion of the elastic portion 150a, the second connection portion 120a is connected to the lower portion of the elastic portion 150a, and the elastic portion 150a is integrally connected with the first and second supporting portions 130aa and 130ab through the bridge 140a, whereby the metal molded product 100a is configured entirely as a single body.

The elastic portion 150a has the same cross-sectional shape in every thickness-wise section of the metal molded product 100a. This is possible because the metal molded product 100a is manufactured through a plating process.

The elastic portion 150a has a shape formed by repeatedly bending a flat plate having an effective width t in an S-shape and the effective width t of the flat plate is uniform overall.

The elastic portion 150a is formed by alternately connecting a plurality of straight portions 153a and a plurality of curved portions 154a. The straight portion 153a connects left and right adjacent curved portions 154a and the curved portion 154a connects upper and lower adjacent straight portions 153a. The curved portions 154a have an arc shape.

The straight portions 153a are disposed at the center portion of the elastic portion 150a and the curved portions 154a are disposed at the edges of the elastic portion 150a. The straight portions 153a are provided in parallel with the width direction so that the curved portions 154a are more easily deformed by contact pressure.

In order to prevent the metal molded product 100a installed on a testing apparatus from separating from a guide plate, a first locking portion 131a is formed at an end of the supporting portion 130a and a second locking portion 132a is formed at another end.

The first locking portion 131a prevents the metal molded product 100a from separating downward from the guide plate and the second locking portion 132a prevents the metal molded product 100a from separating upward from the guide plate.

The first locking portion 131a protrudes outward in the width direction. Accordingly, up-down movement of the metal molded product 100a is restricted.

The second locking portion 132a is provided in a hook shape. The second locking portion 132a includes a first inclined portion 132aa connected with the supporting portion 130a and inclined inward in the width direction, and a second inclined portion 132ba connected at an end with the first inclined portion 132aa, having a free end at another end, and inclined in the inclination direction of the first inclined portion 132aa. The second locking portion 132a is formed in a hook shape by the configuration of the first inclined portion 132aa and the second inclined portion 132ba and another end of the second inclined portion 132ba is supported on the bottom surface of the guide plate. Further, since the second locking portion 132a is more easily elastically deformed in the width direction by the configuration of the first inclined portion 132aa and the second inclined portion 132 ba, so the metal molded product 100 a is easily inserted into a through-hole 210 of the guide plate.

Hereafter, a manufacturing method of the metal molded product 100a according to preferred embodiments of the present disclosure is described.

FIG. 3a is a plan view of a mold 1000 with an internal space 1100 and FIG. 3b is a cross-sectional view of line A-A′ in FIG. 3a.

The mold 1000 may be made of an anodized film, a photoresist, a silicon wafer, or other similar materials. However, preferably, the mold 1000 may be made of an anodized film material. The anodized film refers to a film formed by anodizing metal that is a base material and a pore refers to a hole formed when an anodized film is formed by anodizing metal. For example, when metal that is a base material is aluminum (Al) or an aluminum alloy and the base material is anodized, an anodized film of an aluminum oxide (Al2O3) is formed on the surface of the base material. However, the base material metal is not limited thereto and includes Ta, Nb, Ti, Zr, Hf, Zn, W, Sb, or alloys thereof. The anodized film formed in this way is vertically divided into a barrier layer without a pore therein and a porous layer with pores therein. When the base material having the anodized film with a barrier layer and a porous layer formed on the surface is removed, only the anodized film of the aluminum oxide (A1203) remains. The anodized film may be formed in a structure through which pores are vertically formed and in which the barrier layer formed in anodization is removed or a structure in which the barrier layer formed in anodization remains and an end of the upper and lower ends of pores is closed.

The anodized film has a coefficient of thermal expansion of 2˜3 ppm/° C. Accordingly, when it is exposed to a high-temperature environment, thermal deformation by temperature is small. Therefore, it is possible to manufacture a precise metal molded product 100a without thermal deformation even through the manufacturing environment of the metal molded product 100a is a high-temperature environment.

The metal molded product 100a according to a preferred embodiment of the present disclosure exhibits an effect that it is possible to achieve precision of a shape and a fine shape, which was limited in implementation by a photoresist mold, in that the metal molded product is manufactured using the mold 1000 made of an anodized film material instead of a photoresist mold. Further, it is possible to manufacture an electroconductive contact pin with a thickness of 60 μm using photoresist molds of the related art, but when the mold 1000 made of an anodized film material is used, it is possible to manufacture a metal molded product 100a having a thickness of 80 μm or more and 160 μm or less.

A seed layer 1200 is provided on the bottom surface of the mold 1000. The seed layer 1200 may be provided on the bottom surface of the mold 1000 before an internal space 1100 is formed in the mold 1000. Meanwhile, a supporting substrate (not shown) is formed at the lower portion of the mold 1000, whereby it is possible to improve the handling characteristic of the mold 1000. Further, in this case, the seed layer 1200 may be formed on the top surface of the supporting substrate and the mold 100 with the internal space 1100 may be coupled to the supporting substrate for use. The seed layer 100 may be made of a copper (Cu) material and may be formed by deposition.

The internal space 1100 may be formed by wet-etching the mold 1000 made of an anodized film material. To this end, a photoresist is provided on the top surface of the mold 1000 and patterned, and then an anodized film in a region open by the patterning reacts with an etching solution, whereby the internal space 1100 can be formed.

Thereafter, the metal molded product 100a is formed by performing an electroplating process on the internal space 1100 of the mold 1000. FIG. 4a is a plan view of a mold with an internal space 1100 formed by performing an electroplating process on the internal space 1100 and FIG. 4b is a cross-sectional view of line A-A′ in FIG. 4a.

Since a metal layer is formed while growing in the thickness direction (±z direction) of the mold 1000, the shapes of cross-sections in the thickness direction (±z direction) of the mold 1000 are the same and a plurality of metal layers is stacked in the thickness direction (±z direction) of the metal molded product 100a. The plurality of metal layers includes a first metal layer 101a and a second metal layer 102a. The first metal layer 101a includes, as metal with high wear resistance relative to the second metal layer 102a, rhodium (Rd), platinum (Pt), iridium (Ir), palladium (Pd), or alloys thereof, or a palladium-cobalt (PdCo) alloy, a palladium-nickel (PdNi) alloy, a nickel-phosphor (NiPh) alloy, a nickel-manganese (NiMn) alloy, a nickel-cobalt (NiCo) alloy, or a nickel-tungsten (NiW) alloy. The second metal layer 102a includes, as metal with high electrical conductivity relative to the first metal layer 101a, copper (Cu), silver (Ag), gold (Au), or alloys thereof.

The first metal layer 101a is provided on the bottom surface and the top surface of the metal molded product 100a in the thickness direction (±z direction), and the second metal layer 102a is provided between the first metal layers 101a. For example, in the metal molded product 100a, a first metal layer 101a, a second metal layer 102a, and a first metal layer 101a may be sequentially stacked, and the number of the layers that are stacked may be three or more.

A supporting frame SP is also manufactured through a plating process. In other words, the supporting frame SP and the body of the metal molded product 100a are integrally manufactured by a plating process.

Meanwhile, after the plating process is finished, the temperature is increased to a high level and then the metal layers that have undergone the plating process are pressed by applying pressure, whereby the first metal layer 101a and the second metal layer 102a can be further densified. When a photoresist material is used as a mold, a photoresist exists around metal layers after a plating process is finished, so the process of increasing temperature to a high level and applying pressure cannot be performed. In contrast to this, according to a preferred embodiment of the present disclosure, since the mold 100 made of an anodized film material is provided around the metal layers that have undergone a plating process, it is possible to densify the first metal layer 101a and the second metal layer 102a while minimizing deformation due to a low coefficient of thermal expansion of the anodized film even though the temperature is increased to a high level. Accordingly, as compared with the technique using a photoresist as a mold, it is possible to obtain further densified first metal layer 101a and second metal layer 102a.

When the electroplating process is finished, a process of removing the mold 1000 and the seed layer 1200 is performed. When the mold 1000 is made of an anodized film material, the mold 1000 is removed using a solution that selectively reacts with the anodized film material. Further, when the seed layer 1200 is made of a copper (Cu) material, the seed layer 1200 is removed using a solution that selectively reacts with copper (Cu).

The body of the metal molded product 100a is coupled to the supporting frame SP to be separable through a cutting portion 135a. The metal molded product 100a is manufactured in batches of tens of thousands to hundreds of thousands by using a wafer-sized anodized film mold 1000. The bodies of a large number of metal molded products 100a are manufactured while connected to the supporting frame SP in the manufacturing process, and the bodies of the manufactured metal molded products 100a are individually detached from the supporting frame SP and then inserted and installed in through-holes of a guide plate. The cutting portion 135a is formed to be able to easily detach the body of the metal molded product 100a from the supporting frame SP. The cutting portion 135a serves to fix the body of the metal molded product 100a to the supporting frame SP when manufacturing the metal molded product 100a, and serves to enable the body of the metal molded product 100a to be easily separated from the supporting frame SP when separating the body of the metal molded product 100a. The distance t of line width of the cutting portion 135 a may have a range of 2 μm or more and 6 μm or less so that the body of the metal molded product 100a can be easily separated from the supporting frame SP. The distance of line width of the cutting portion 135a may be the smallest line width among multiple line widths. In this case, the line width of an end is excluded from the range of the multiple line widths.

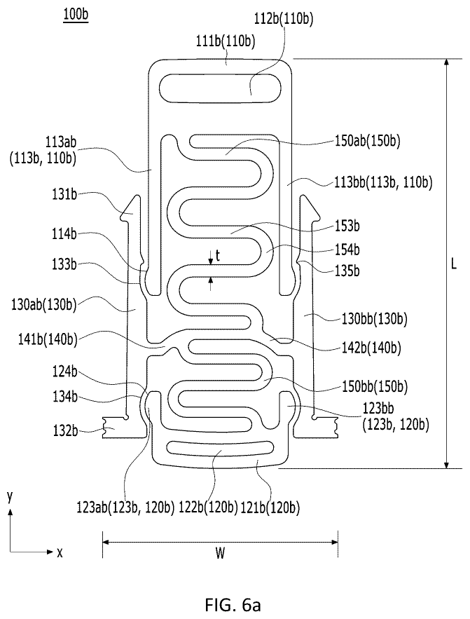

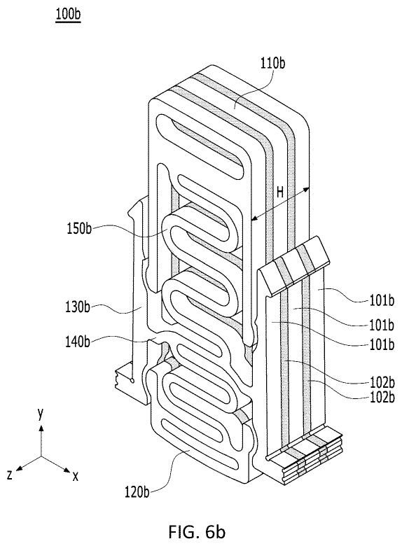

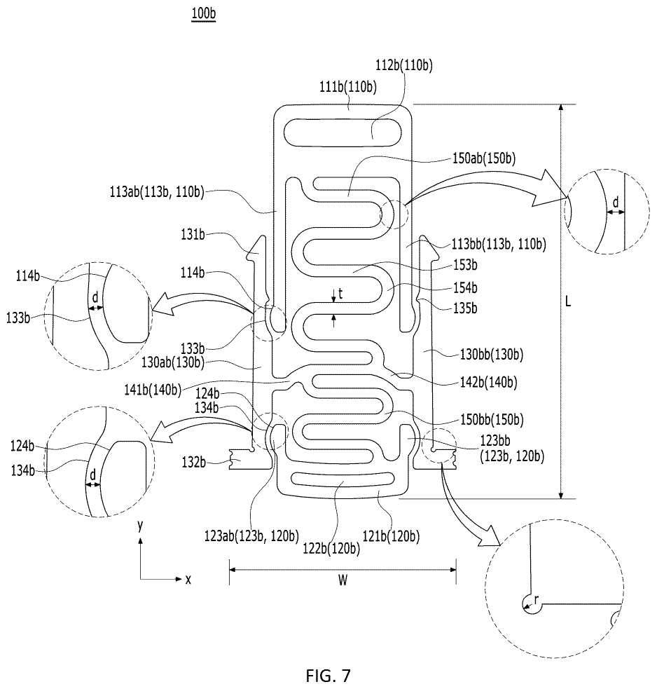

Metal molded product (100b) according to second embodiment FIG. 6a is a plan view of a metal molded product according to a second preferred embodiment of the present disclosure, FIG. 6b is a perspective view of the metal molded product according to the second preferred embodiment of the present disclosure, and FIG. 7 is a view showing FIG. 6a together with an enlarged view of a portion of FIG. 6a.

A metal molded product 100b includes a first connection portion 110b, a second connection portion 120b, a supporting portion 130b longitudinally extending, an elastic portion 150b connected to the first connection portion 110b and the second connection portion 120b and being able to longitudinally elastically deform, and a bridge 140b connecting the elastic portion 150b and the supporting portion 130b.

The first connection portion 110b, the second connection portion 120b, the supporting portion 130b, the bridge 140b, and the elastic portion 150b are integrally provided. The first connection portion 110b, the second connection portion 120b, the supporting portion 130b, the bridge 140b, and the elastic portion 150b are manufactured all at once using a plating process. The metal molded product 100b has a plurality of different metal layers stacked in the thickness direction (±z direction). The plurality of different metal layers includes a first metal layer 101 and a second metal layer 102.

The first connection portion 110b includes a first contact portion 111b that comes into contact with a terminal of a test object and a flange 113b extending downward from the first connection portion 111b. The first flange 113b is provided between the elastic portion 150b and the supporting portion 130b to cover at least a portion of the elastic portion 150b from the outside thereof. When the elastic portion 150b is deformed, the first contact portion 111b and the first flange 113b are integrally operated.

The first contact portion 111b has a first cavity 112b so that a contact surface can be more easily deformed by pressure applied by a test object. The upper surface of the first contact portion 111b over the first cavity 112b is the portion that comes into contact with a terminal of a test object and the lower surface of the first contact portion 111b under the first cavity 112b is connected to the elastic portion 150b. The first cavity 112b is formed in the thickness direction (±z direction) and the left and right portions thereof are formed as an empty space with curved left and right sides so that the upper surface of the first contact portion 111b is more easily deformed.

The first contact portion 110b is connected to the elastic portion 150b, so the first connection portion 110b can be elastically vertically moved by contact pressure. When a test object is tested, a terminal of the test object is moved downward in contact with the top surface of the first connection portion 110b. Accordingly, the elastic portion 150b connected with the first connection portion 110b is compressively deformed.

The flange 113b of the first connection portion 110b extends downward from the first contact portion 111b and is configured to cover at least a portion of the side of the elastic portion 150b. In this configuration, the first flange 113b continues from the width-directional end of the first contact portion 111b and extends downward. The first flange 113b extends downward (−y direction) from the first contact portion 111b and at least a portion of the first flange 113b is provided between the elastic portion 150b and the supporting portion 130b.

The elastic portion 150b is elastically deformed such that the first connection portion 110b and the second connection portion 120b are moved with respect to each other. The bridge 140b connects the elastic portion 150b and the supporting portion 130b to each other. In other words, the bridge 140b connects the elastic portion 150b to the supporting portion 130b. The elastic portion 150b is divided into an upper elastic portion 150ba positioned over the bridge 140b and a lower elastic portion 150bb positioned under the bridge 140b.

When the elastic portion 150b is compressed (in more detail, the upper elastic portion 150ba is compressed), the first flange 113b is moved downward (−y direction) in the space between the elastic portion 150b to the supporting portion 130b. On the contrary, when the elastic portion 150b is restored, the first flange 113b is moved upward (+y direction) in the space between the elastic portion 150b and the supporting portion 130b.

The supporting portion faces an inner wall of a guide plate and extends in the longitudinal direction (±y direction).

The supporting portion 130b includes a first supporting portion 130ab positioned on a side of the metal molded product 100b and a second supporting portion 130bb positioned on another side of the metal molded product 100b. The width-directional dimension of the first contact portion 111b is smaller than the dimension between the first supporting portion 130ab and the second supporting portion 130bb, and the first flange 113b is positioned in the region between the first supporting portion 130ab and the second supporting portion 130bb.

The first supporting portion 130ab and the second supporting portion 130bb are formed in the longitudinal direction of the metal molded product 100b, and the first supporting portion 130ab and the second supporting portion 130bb are integrally connected to the bridge 140b extending in the width direction of the metal molded product 100b. The first connection portion 110b is connected to the upper portion of the elastic portion 150b, the second connection portion 120b is connected to the lower portion of the elastic portion 150b, and the elastic portion 150b is integrally connected with the first and second supporting portions 130ba and 130bb through the bridge 140b, whereby the metal molded product 100b is configured entirely as a single body.

The first flange 113b includes a first left flange 113ab positioned at a side of the elastic portion 150b and a first right flange 113bb positioned at another side of the elastic portion 150b opposite to the first left flange 113ab. The first left flange 113ab and the first right flange 113bb are connected to the first contact portion 111b.

The first flange 113b of the first connection portion 110b is positioned to overlap the supporting portion 130b in the width direction. In detail, the first flange 113b extends from the first contact portion 111b such that at least a portion of the first flange 113b is positioned in the space between the supporting portion 130b and the elastic portion 150b. In more detail, at least a portion of the first left flange 113ab is positioned between the first supporting portion 130ab and the elastic portion 150b and at least a portion of the first right flange 113bb is positioned between the elastic portion 150b and the second supporting portion 130bb.

When the elastic portion 150b is compressed, the first left flange 113ab is moved downward (−y direction) in the space between the elastic portion 150b and the first supporting portion 130ab and the first right flange 113bb is moved downward (−y direction) in the space between the elastic portion 150b and the second supporting portion 130bb. When the elastic portion 150b is restored, the first left flange 113ab is moved upward (+y direction) in the space between the elastic portion 150b and the first supporting portion 130ab and the first right flange 113bb is moved upward (+y direction) in the space between the elastic portion 150b and the second supporting portion 130bb.

When an eccentric pressing force is applied by a terminal that is in contact with the first connection portion 110b and the first connection portion 110b is inclined to the left, the first left flange 113ab comes into contact with the first supporting portion 130ab and the first right flange 113bb comes into contact with the second supporting portion 130bb. As a result, the upper end of the first supporting portion 130ab supports the first left flange 113ab and the second supporting portion 130bb supports the first right flange 113bb. Accordingly, the first connection portion 110b is prevented from excessively inclining to the left. Further, when an eccentric pressing force is applied by a contact terminal that is in contact with the first connection portion 110b and the first connection portion 110b is inclined to the right, the first left flange 113ab comes into contact with the first supporting portion 130ab and the first right flange 113bb comes into contact with the second supporting portion 130bb. As a result, the upper end of the second supporting portion 130bb supports the second left flange 113bb and the first supporting portion 130ab supports the lower end of the first left flange 113ab. Accordingly, the first connection portion 110b is prevented from excessively inclining to the right.

When the metal molded product 110b is inserted in a guide plate, at least a portion of the end portion of the first flange 113b is positioned in a guide hole of the guide plate. The first flange 113b has a flat plate shape, and when forward and backward eccentric pressing forces are applied to the metal molded product 110b, the first flange 113b can come into contact with the guide hole, so the first flange 113b can resist excessive forward and backward bending deformation.

According to a preferred embodiment, as described above, even though an eccentric pressing force is applied in the left and right direction, the metal molded product 110b is prevented from deforming while excessively inclining to the left and right by the configuration of the first flange 113b and the supporting portion 130b. Further, even though an eccentric pressing force is applied forward and backward, the metal molded product 110b is prevented from deforming while excessively inclining to forward and backward by the configuration of the first flange 113b coming in contact with the inner wall of a through-hole 31.

A first convex portion 114b protruding toward the supporting portion 130b is formed at the free end of the first flange 113b. A first concave portion 133b is formed on the supporting portion 130b to correspond to the position of the first convex portion 114b. By the configuration of the first convex portion 114b and the first concave portion 133b, the first flange 113b remains spaced apart from the supporting portion 130b before the first flange 113b is moved downward, and when the first flange 113b is moved downward, the first flange 113b smoothly comes into contact with the inner surface of the supporting portion 130b and additionally moves downward while maintaining the contact state. In this configuration, the first convex portion 114b and the first concave portion 133b are spaced apart and opposite each other and a gap is formed between the first convex portion 114b and the first concave portion 133b. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the first convex portion 114b and the first concave portion 133b, it is possible to make the metal molded product 100b have a compact structure in the width direction (±x direction) while increasing the total thickness dimension H.

When the elastic portion 150b is not compressed, the first flange 113b and the supporting portion 130b are spaced apart from each other. When the elastic portion 150b is compressed and the first flange 113b is correspondingly moved downward (−y direction), the first flange 113b comes into contact with the inner surface of the supporting portion 130b, thereby forming a current path. In detail, when the first flange 113b is moved downward (−y direction), the first convex portion 114b of the first flange 113b departs from the corresponding position of the first concave portion 133b and comes into contact with the inner surface of the supporting portion 130b, thereby forming a current path. The first flange 113b and the supporting portion 130b are spaced apart from each other, so they do not interfere with deformation of the elastic portion 150b before the elastic portion 150b is compressed, and thereafter, when the elastic portion 150b is compressed, the outer surface of the first flange 113b and the inner surface of the supporting portion 130b come into contact with each other to form a current path between the supporting portion 130b and the first flange 113b.

The bridge 140b includes a first bridge 141b connecting the elastic portion 150b and the first supporting portion 130ab and a second bridge 142b connecting the elastic portion 150b and the second supporting portion 130bb. The first bridge 141b connects the elastic portion 150b and the first supporting portion 130ab and the second bridge 142b connects the elastic portion 150b and the second supporting portion 130bb.

The first bridge 141b and the second bridge 142b may be at the same positions or different positions in the longitudinal direction. According to a preferred embodiment of the present disclosure, the first bridge 141b and the second bridge 142b are provided at the same positions in the longitudinal direction.

The bridge 140b prevents foreign substances that have come inside from above from moving to the second connection portion 120b and foreign substances that have come inside from under also from moving to the first connection portion 110b. By restricting movement of foreign substances that have come inside, it is possible to prevent interference with the operation of the first and second connection portions 110b and 120b by foreign substances.

According to a preferred embodiment of the present disclosure, a stopper with which the lower end of the first flange 113b comes into contact when the first connection portion 110b is moved down is included, and the first flange 113b comes into contact with the stopper before a maximum compression state of the elastic portion 150b. In more detail, when the first flange 113b is moved downward, the free end of the first flange 113b can come into contact with the bridge 140b. Since the first flange 113b is moved downward and the lower end of the first flange 113b comes into contact with the bridge 140b, additional descending of the first contact portion 111b is stopped. Accordingly, the bridge 140b functions as a stopper that restricts additional descending of the first flange 113b. When the first flange 113b is in contact with the stopper (bridge 140b), straight portions 153b adjacent up and down are not in contact with each other. Although the bridge 140b functions as a stopper in the above description, configurations other than the bridge 140b may be a stopper that restricts descending of the first flange 113b.

The second connection portion 120b comes into contact with a connection target (more preferably, a pad of a circuit board).

The second connection portion 120b includes a second contact portion 121b that comes into contact with a pad of a circuit board and a second flange 123b extending upward from the second contact portion 121b and covering at least a portion of the elastic portion 150b. When the elastic portion 150b is deformed, the second contact portion 121b and the second flange 123b are integrally operated.

The second contact portion 121b has a second cavity 122b so that a contact surface can be more easily deformed by pressure by a test object. The lower surface of the second contact portion 121b over the second cavity 122b is the portion that comes into contact with a pad of a circuit board and the upper surface of the second contact portion 111b under the second cavity 122b is connected to the elastic portion 150b. The second cavity 122b is formed in the thickness direction (±z direction) and the left and right portions thereof are formed as an empty space with curved left and right sides so that the upper surface of the second contact portion 121b is more easily deformed.

The second connection portion 120b is connected to the elastic portion 150b, so it can be elastically vertically moved by contact pressure.

When a test object is tested, the elastic portion 150b is compressively deformed while a pad of a circuit board comes into contact with the bottom surface of the second connection portion 120b. The second connection portion 120b comes into contact with the supporting portion 130b while moving upward.

The second flange 123b of the second connection portion 120b extends upward from the second contact portion 121b and is configured to cover at least a portion of the elastic portion 150b. The second flange 123b extends upward (+y direction) from the second contact portion 121b and at least a portion of the second flange 123b is provided between the elastic portion 150b and the supporting portion 130b.

When the elastic portion 150b is compressed (in more detail, the lower elastic portion 150bb is compressed), the second flange 123b is moved upward (+y direction) in the space between the elastic portion 150b to the supporting portion 130b. On the contrary, when the elastic portion 150b is restored, the second flange 123b is moved downward (−y direction) in the space between the elastic portion 150b and the supporting portion 130b.

The second flange 123b includes a second left flange 123ba positioned at a side of the elastic portion 150b and a second right flange 123bb positioned at another side of the elastic portion 150b opposite to the second left flange 123ba. The second left flange 123ba and the second right flange 123bb are connected to the second contact portion 111b.

The second flange 123b of the second connection portion 120b is positioned to overlap the supporting portion 130b in the width direction. In detail, the second flange 123b extends from the second contact portion 121b such that at least a portion of the second flange 123b is positioned in the space between the supporting portion 130b and the elastic portion 150b. In more detail, at least a portion of the second left flange 123ba is positioned between the first supporting portion 130ab and the elastic portion 150b and at least a portion of the second right flange 123bb is positioned between the elastic portion 150b and the second supporting portion 130bb.

When the elastic portion 150b is compressed, the second left flange 123ba is moved upward (+y direction) in the space between the elastic portion 150b and the first supporting portion 130ab and the second right flange 123bb is moved upward (+y direction) in the space between the elastic portion 150b and the second supporting portion 130bb. When the elastic portion 150b is restored, the second left flange 123ba is moved downward (−y direction) in the space between the elastic portion 150b and the first supporting portion 130ab and the second right flange 123bb is moved downward (−y direction) in the space between the elastic portion 150b and the second supporting portion 130bb.

A second convex portion 124b protruding toward the supporting portion 130b is formed at the free end of the second flange 123b. A second concave portion 134b is formed on the supporting portion 130b to correspond to the position of the second convex portion 124b. By the configuration of the second convex portion 124b and the second concave portion 134b, the second flange 123b remains spaced apart from the supporting portion 130b before the second flange 123b is moved upward, and when the second flange 123b is moved upward, the second flange 123b smoothly comes into contact with the inner surface of the supporting portion 130b and additionally moves upward while maintaining the contact state. In this configuration, the second convex portion 124b and the second concave portion 134b are spaced apart and opposite each other and a gap is formed between the second convex portion 124b and the second concave portion 134b. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the second convex portion 124 b and the second concave portion 134b, it is possible to make the metal molded product 100b have a compact structure in the width direction (±x direction) while increasing the total thickness dimension H.

When the elastic portion 150b is not compressed, the second flange 123b and the supporting portion 130b are spaced apart from each other. When the elastic portion 150b is compressed and the second flange 123b is correspondingly moved upward (+y direction), the second flange 123b comes into contact with the inner surface of the supporting portion 130b, thereby forming a current path. In more detail, when the second flange 123b is moved upward (+y direction), the second convex portion 124b of the second flange 123b comes into contact with the inner surface of the supporting portion 130b, thereby forming a current path. The second flange 123b and the supporting portion 130b are spaced apart from each other, so they do not interfere with deformation of the elastic portion 150b before the elastic portion 150b is compressed, and thereafter, when the elastic portion 150b is compressed, the outer surface of the second flange 123b and the inner surface of the supporting portion 130b come into contact with each other to form a current path between the supporting portion 130b and the second flange 123b.

The elastic portion 150b has the same cross-sectional shape in every thickness-wise section of the metal molded product 100b. This is possible because the metal molded product 100b is manufactured through a plating process. The elastic portion is connected to at least any one of the first connection portion 110b and the second connection portion 120b and can elastically deform in the longitudinal direction (±y direction). The elastic portion 150b is formed by alternately connecting a plurality of straight portions 153b and a plurality of curved portions 154b. The straight portion 153b connects left and right adjacent curved portions 154b and the curved portion 154b connects upper and lower adjacent straight portions 153b. The curved portions 154b have an arc shape. The straight portions 153b are disposed at the center portion of the elastic portion 150b and the curved portions 154b are disposed at the edges of the elastic portion 150b. The straight portions 153b are provided in parallel with the width direction so that the curved portions 154b are more easily deformed by contact pressure.

In this configuration, the curved portions 154b of the elastic portion 150b and first flange 113b are space apart and opposite each other, and a gap is formed between the curved portions 154b and the first flange 113b. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the curved portions 154b and the first flange 113b, it is possible to make the metal molded product 100b have a compact structure in the width direction (±x direction) while increasing the total thickness dimension H. Further, it is possible to prevent the elastic portion 150b from excessively tilting in the width direction (±x direction).

Meanwhile, any one of (i) the gap between the first convex portion 114b and the first concave portion 133b, (ii) the gap between the second convex portion 124b and the second concave portion 134b, and (iii) the gap between the curved portions 154b of the elastic portion 150b and the first flange 113b may be the smallest gap amount several gaps.

In order to prevent the metal molded product 100b installed on a testing apparatus from separating from a guide plate, a first locking portion 131b is formed at an end of the supporting portion 130b and a second locking portion 132b is formed at another end. The first locking portion 131b and the second locking portion 132b are configured in a shape protruding outward in the width direction. Accordingly, the metal molded product 100b is not separated from the guide plate after being inserted in the guide plate.

The first locking portion 131b prevents the metal molded product 100b from separating downward from the guide plate and the second locking portion 132b prevents the metal molded product 100b from separating upward from the guide plate.

The metal molded product 100b has intersections where two portions intersect in the x-y plane. The second locking portion 132b and the supporting portion 130b form an intersection where two portions intersect in the x-y plane. An intersection has an open hole. Since an open hole is formed, a rounded corner is not formed at the intersection. The radius r of the open holes may have a range of 1 μm or more and 3 μm or less. The open hole at the intersection where the second locking portion 132b and the supporting portion 130b intersect may be an open hole with the smallest radius among several open holes. The aspect ratio (H:r) of the total thickness dimension H and the radius r of the open holes has a range of 26:1 or more and 160:1 or less. Accordingly, it is possible to enable the metal molded product 100b to come into close contact with the inner wall of a guide hole of a guide plate while minimizing a loss of the metal molded product 100b.

Metal molded product (100c) according to third embodiment

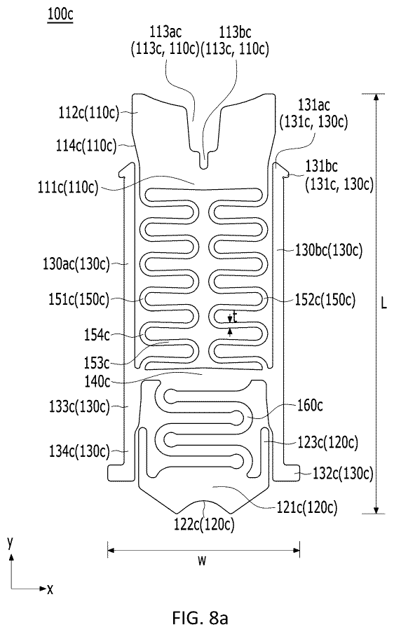

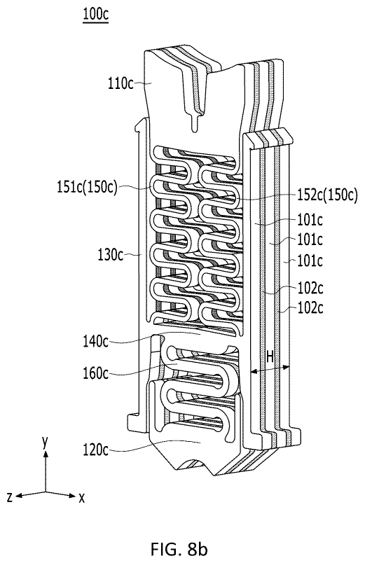

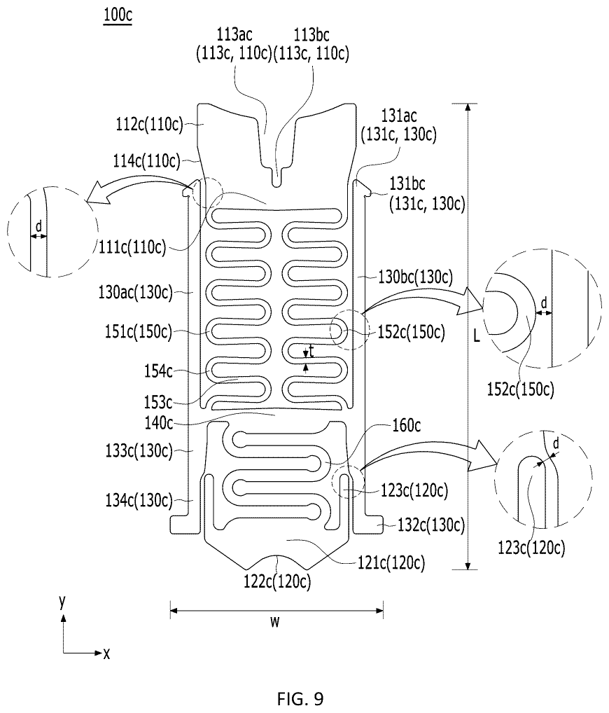

FIG. 8a is a plan view of a metal molded product according to a third preferred embodiment of the present disclosure, FIG. 8b is a perspective view of the metal molded product according to the third preferred embodiment of the present disclosure, and FIG. 9 is a view showing FIG. 8a together with an enlarged view of a portion of FIG. 8a.

A metal molded product 100c includes a first connection portion 110c, a second connection portion 120c, a supporting portion 130c longitudinally extending, a bridge 140c extending in the width direction and connected at both sides to the supporting portion 130c, a first elastic portion 150c connecting the first connection portion 110c and the bridge 140c, and a second elastic portion 160c connecting the second connection portion 120c and the bridge 140c.

An end of the first elastic portion 150c is connected to the first connection portion 110c and another end is connected to the bridge 140c. An end of the second elastic portion 160c is connected to the second connection portion 120c and another end is connected to the bridge 140c.

The first connection portion 110c, the second connection portion 120c, the supporting portion 130c, the bridge 140c, the first elastic portion 150c, and the second elastic portion 160c are integrally provided. The first connection portion 110c, the second connection portion 120c, the supporting portion 130c, the bridge 140c, the first elastic portion 150c, and the second elastic portion 160c are manufactured all at once using a plating process.

A plurality of metal layers is stacked in the thickness direction of the metal molded product 100c. The plurality of metal layers includes a first metal layer 101 and a second metal layer 102.

An end of the first connection portion 110c is a free end and another end is connected to the first elastic portion 150c, so it can be elastically vertically moved by contact pressure.

When a test object is tested, a connection terminal of the test object is moved downward in contact with the top surface of the first connection portion 110c. Accordingly, the first elastic portion 150c connected with the first connection portion 110c is compressively deformed. The first connection portion 110c comes into contact with the supporting portion 130c while moving downward.

An expansion portion 114c recessed inward in the width direction is formed on the side of the first connection portion 110c. By the configuration of the expansion portion 114c, the first connection portion 110c and the supporting portion 130c are spaced apart from each other before a connection terminal of a test object comes into contact with the first connection portion 110c. Since the first connection portion 110c and the supporting portion 130c are spaced apart from each other, the first elastic portion 150c can be more easily compressively deformed when a pressing force is applied by a connection terminal. In this configuration, the first connection portion 110c and the supporting portion 130c are spaced apart and opposite each other and a gap is formed between the first connection portion 110c and the supporting portion 130c. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the first connection portion 110c and the supporting portion 130c, it is possible to make the metal molded product 100c have a compact structure in the width direction (±x direction) while increasing the total thickness dimension H. Further, it is possible to prevent the first connection portion 110c from excessively tilting in the width direction (±x direction) when an eccentric pressing force is applied to the first connection portion 110c.

When a connection terminal of a test object is moved downward by a predetermined distance in contact with the first connection portion 110c, the gap between the first connection portion 110c and the supporting portion 130c decreases, so the side of the first connection portion 110c comes into contact with the supporting portion 130c. Since the first elastic portion 150c is compressed by a pressing force by the connection terminal, as described above, the first connection portion 110c comes into contact with the supporting portion 130c, thereby forming a current path.

The first connection portion 110c includes a base portion 111c connected with the first elastic portion 150c and a protruding portion 112c extending upward from the base portion 111c. At least two or more protruding portions 112c may be provided. By the plurality of protruding portions 112c, multi-contact is achieved between the first connection portion 110c and a connection terminal 410. The top surfaces of the protruding portions 112c come into contact with the bottom surface of a connection terminal of a test object. The connection terminal of a test object may be provided in a solder ball type, and in this case, the top surfaces of the protruding portions 112c are formed to at least partially have a curvature, so the top surfaces come into contact with the bottom surface of the connection terminal as if wrapping around it.

A groove portion 113c is provided between the two protruding portions 112c. When a process of bringing the first connection portion 110c and an external terminal into contact with each other is performed multiple times, particles from the external terminal may settle on the surfaces of the protruding portions 112c. However, since the groove portion 113c is formed between the two protruding portions 112c and the top surfaces of the protruding portions 112c are inclined toward the groove portion 113c, particles are naturally guided to the groove portion 113c. As a result, it is possible to minimize the phenomenon in which particles interfere with electrical connection while accumulating on the top surfaces of the protruding portions 112c.

Further, after the first connection portion 110c moves down and comes into close contact with the supporting portion 130c, the ends of the two protruding portions 112c close toward each other by the configuration of the groove portion 113, thereby enabling the protruding portions 112c to more closely come into contact with a connection terminal. The groove portion 114c may include a first groove portion 113ac positioned at the upper portion and a second groove portion 113bc positioned under the first groove portion 113ac and having a width smaller than the inner width of the first groove portion 113ac. Accordingly, it is possible to enable the two protruding portions 112c to more easily close with the bottom of the second groove portion 113bc therebetween. Further, the dual groove structure of the first groove portion 113ac and the second groove portion 113bc prevents reduction of the rigidity of the two protruding portions 112c.

An end of the second connection portion 120c is a free end and another end is connected to the second elastic portion 160c, so it can be elastically vertically moved by contact pressure.

The second connection portion 120c includes a body portion 121c connected with the second elastic portion 160c and a flange 123c extending from the body portion 121c and positioned inside the supporting portion 130c. When the second elastic portion 160c is compressed, the flange 123c can come into contact with the inner surface of the supporting portion 130c.

The body portion 121c has a concave portion 122c. Contact points protruding downward are formed at both sides of the concave portion 122, respectively, whereby multi-contact is achieved between the second connection portion 120c and a connection pad.

The flange 123c extends upward from the side of the body portion 121c in parallel with the supporting portion 130c while it is spaced apart from the supporting portion 130c.

In this configuration, the flange 123c and the supporting portion 130c are spaced apart and opposite each other and a gap is formed between the flange 123c and the supporting portion 130c. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the flange 123 c and the supporting portion 130c, it is possible to make the metal molded product 100c have a compact structure in the width direction (±x direction) while increasing the total thickness dimension H. Further, it is possible to prevent the second connection portion 120c from excessively tilting in the width direction (±x direction) when an eccentric pressing force is applied to the second connection portion 120c.

The flange 123c is positioned between the supporting portion 130c and the second elastic portion 160c in the width direction.

The supporting portion 130c includes a thin portion formed at a position corresponding to the position of the flange 123c and a thick portion 133c formed over the thin portion 134 and having a width larger than the width of the thin portion 134c. The outer side of the supporting portion 130c is vertically formed because it comes into close contact with a guide hole of a guide plate, but the inner side of the supporting portion 130c has the thin portion 134c and the thick portion 133c that are different in width. The thin portion 134c is a portion with a smaller width relative to the thick portion 133c. By the configuration of the inner side of the supporting portion 130c having the thin portion 134c and the thick portion 133c, the line width of the supporting portion 130c increases as it goes upward. When the flange 123c is moved upward, the flange 123c is spaced from the supporting portion 130c at the position of the thin portion 134c and comes into contact with the supporting portion 130c at the position of the thick portion 133c.

When the second connection portion 120c is pressed in contact with a pad of a circuit board, the second elastic portion 160c is compressively deformed, whereby the second connection portion 120c is moved upward. Since the second connection portion 120c is spaced apart from the supporting portion 130c before the second connection portion 120c is moved upward, the second elastic portion 160c is more easily compressively deformed. When the second connection portion 120c is moved upward by a predetermined distance, the second connection portion 120c comes into contact with the supporting portion 130c. In more detail, before the second elastic portion 160c is compressively deformed, the flange 123c of the second connection portion 120c is spaced apart from the thin portion 134c of the supporting portion 130c. When the second elastic portion 160c is compressively deformed, the second connection portion 120c is moved upward and the flange 123c of the second connection portion 120c comes into contact with the thick portion 133c. As described above, as the second elastic portion 160c is compressed, the second connection portion 120c comes into contact with the supporting portion 130c, thereby forming a current path.

The supporting portion 130c includes a first supporting portion 130ac provided at the left side and a second supporting portion 130bc provided at the right side. The bridge 140c extends in the width direction of the metal molded product 100c and connects the first supporting portion 130ac and the second supporting portion 130bc.

The upper side and the lower side of the supporting portion 130c can close toward or open away from each other in the width direction with the bridge 140c therebetween. By the configuration of the supporting portion 130c of which the upper side and the lower side close or open in the width direction, it is possible to more easily achieve the process of inserting and installing the metal molded product 100c into a guide hole of a guide plate and the process of replacing metal molded product 100c.

The first elastic portion 150c is disposed over the bridge 140c and the second elastic portion 160c is disposed under the bridge 140c. The first elastic portion 150c and the second elastic portion 160c are compressed or extended with the bridge 140c therebetween. The bridge 140c is fixed to the first and second supporting portions 130ac and 130bc, thereby performing a function of restricting positional movement of the first and second elastic portions 150c and 160c when the first and second elastic portions 150c and 160c are compressed.

By the bridge 140c, the region where the first elastic portion 150c is disposed and the region where the second elastic portion 160c is disposed are separated. Accordingly, foreign substances that have come inside from above are prevented from moving to the second elastic portion 160c and foreign substances that have come inside from under also are prevented from moving to the first elastic portion 150c. Accordingly, by restricting movement of foreign substances that has come inside the supporting portion 130c, it is possible to interference with the operation of the first and second elastic portions 150c and 160c due to foreign substances.

The first supporting portion 130ac and the second supporting portion 130bc are formed in the longitudinal direction of the metal molded product 100c, and the first supporting portion 130ac and the second supporting portion 130bc are integrally connected to the bridge 140c extending in the width direction of the metal molded product 100c. The first and second elastic portions 150c and 160c are integrally connected through the bridge 140c, whereby the metal molded product 100c is configured entirely as a single body.

The first and second elastic portions 150c and 160c are formed by alternately connecting a plurality of straight portions 153c and a plurality of curved portions 154c. The straight portion 153c connects left and right adjacent curved portions 154c and the curved portion 154c connects upper and lower adjacent straight portions 153c. The curved portions 154c have an arc shape.

The straight portions 153c are disposed at the center portions of the first and second elastic portions 150c and 160c and the curved portions 154c are disposed at the edges of the first and second elastic portions 150c and 160c. The straight portions 153c are provided in parallel with the width direction so that the curved portions 154c are more easily deformed by contact pressure.

In this configuration, the curved portions 154c of the first and second elastic portions 150c and 160c and the supporting portion 130c are spaced apart and opposite each other and a gap is formed between the curved portions 154c and the supporting portion 130c. The aspect ratio (H:d) of the total thickness dimension H and the distance d of gaps has a range of 13:1 or more and 80:1 or less. For example, the distance d of a gap may be 4 μm and the height H of a gap may be 100 μm . By increasing the aspect ratio of the gap space between the curved portions 154c and the supporting portion 130c, it is possible to make the metal molded product 100c have a compact structure in the width direction (±x direction) while increasing the total thickness dimension H. Further, it is possible to prevent the first and second elastic portions 150c and 160c from excessively tilting in the width direction (±x direction).

Meanwhile, any one of (i) the gap between the first connection portion 110c and the supporting portion 130c, (ii) the gap between the flange 123c and the supporting portion 130c, and (iii) the gap between the curved portions 154 of the first and second elastic portions 150c and 160c and the supporting portion 130c may be the smallest gap among several gaps.

The portions of the first and second elastic portions 150c and 160c that are connected with the bridge 140c are the curved portions 154c of the first and second elastic portions 150c and 160c. Accordingly, the first and second elastic portions 150c and 160c maintain elasticity with respect to the bridge 140c.

The first elastic portion 150c requires a compression amount that enables the first connection portion 110c of the metal molded product 100c to stably come into contact with a connection terminal of a test object, whereas the second elastic portion 160c requires a compression amount that enables the second connection portion 120c of the metal molded product 100c to stably come into contact with a connection pad of a circuit board. Accordingly, the spring coefficient of the first elastic portion 150c and the spring coefficient of the second elastic portion 160c may be different from each other. For example, the length of the first elastic portion 150c and the length of the second elastic portion 160c may be different from each other. Alternatively, the width-directional dimension of the first elastic portion 150c and the width-directional dimension of the second elastic portion 160c may be different from each other.

Alternatively, one second elastic portion 160c may be provided and at least two or more first elastic portions 150c may be provided. As shown in the figures, one second elastic portion 160c is be provided, but the first elastic portion 150c includes a 1-1 elastic portion 151c connected at an end to the first connection portion 110c and connected at another end to the bridge 140c and a 1-2 elastic portion 152c spaced apart from the 1-1 elastic portion 151c and connected at an end to the first connection portion 110c and connected at another end to the bridge 140c. In this case, the width-directional dimensions of the 1 -1 elastic portion 151 c and the 1-2 elastic portion 152 c may be smaller than the width-directional dimensions of the second elastic portion 160c.

The 1 -1 elastic portion 151 c and the 1-2 elastic portion 152 c are provided in a left-right symmetrical shape. In other words, the 1-1 elastic portion 151c and the 1-2 elastic portion 152c are symmetric to each other with respect to an axis between the 1-1 elastic portion 151c and the 1-2 elastic portion 152c. Accordingly, the first connection portion 110c can be more stably vertically moved.

In order to prevent the metal molded product 100c installed on a testing apparatus from separating from a guide plate, a first locking portion 131c is formed at an end of the supporting portion 130b and a second locking portion 132c is formed at another end.

The first locking portion 131c prevents downward separation of the metal molded product 100c and the second locking portion 132c prevents upward separation of the metal molded product 100c.

The first locking portion 131c is composed of an inclined portion 131ac inclined upward and inward in the width direction and a protruding step 131bc protruding outward in the width direction. By the configuration of the inclined portion 131ac, it becomes easy to insert the metal molded product 100c into a guide hole of a guide plate. Further, by the configuration of the protruding step 131bc, the metal molded product 100c is prevented from falling down from a guide hole after being installed in the guide hole.

The second locking portion 132c protrudes outward in the width direction. Accordingly, up-down movement of the metal molded product 100c is restricted.

Metal molded product (100d) according to fourth embodiment

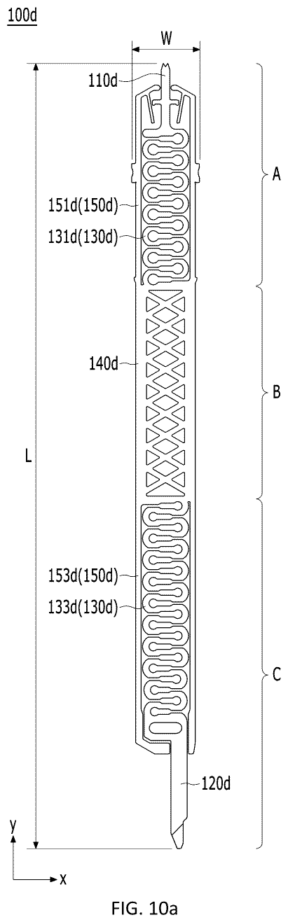

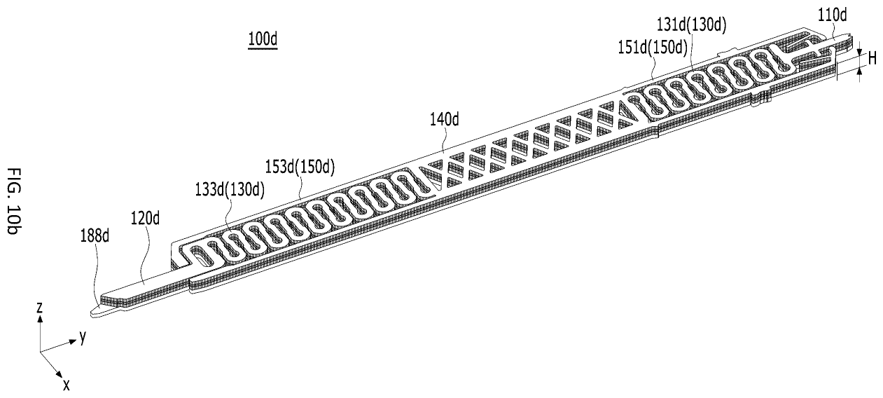

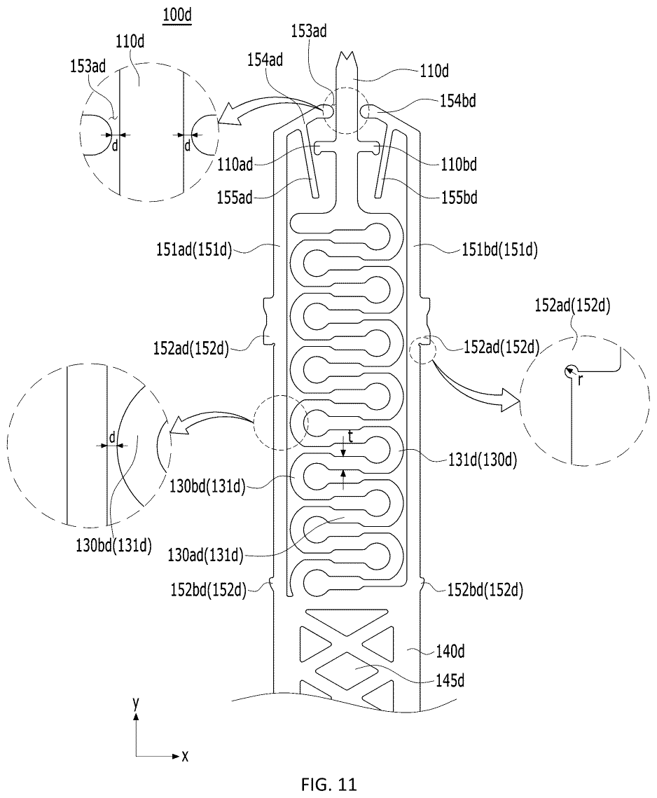

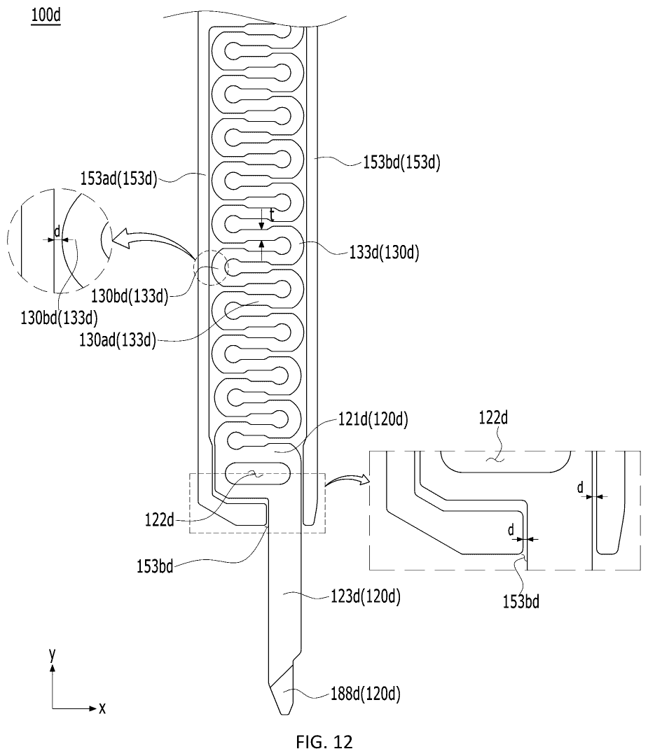

FIG. 10a is a plan view of a metal molded product according to a fourth preferred embodiment of the present disclosure, FIG. 10b is a perspective view of the metal molded product according to the fourth preferred embodiment of the present disclosure, and FIG. 11 and FIG. 12 are views showing FIG. 10a together with an enlarged view of a portion of FIG. 10a.

A metal molded product 100d includes a first connection portion 110d, a second connection portion 120d, and an elastic portion 130d connected to the first connection portion 110d and/or the second connection portion 120d and being able to elastically deform in the longitudinal direction (y direction). A first contact point of the first connection portion 110d is connected to a circuit wiring part and the second connection portion 120d is connected to a test object. The elastic portion 130d enables the first connection portion 110d and the second connection portion 120d to elastically move in the longitudinal direction of the metal molded product 100d. The first connection portion 110d can be elastically relatively moved in the longitudinal direction (±y direction) with respect to the second connection portion 120d by the elastic portion 130d.

The first connection portion 110d, the second connection portion 120d, and the elastic portion 130d are integrally provided. The first connection portion 110d, the second connection portion 120d, and the elastic portion 130d are manufactured all at once using a plating process.

The elastic portion 130d is formed by alternately connecting a plurality of straight portions 130ad and a plurality of curved portions 130bd. The straight portion 130ad connects left and right adjacent curved portions 130bd and the curved portion 130bd connects upper and lower adjacent straight portions 130ad. The curved portions 130bd have an arc shape.

The straight portions 130ad are disposed at the center portion of the elastic portion 130d and the curved portions 130bd are disposed at the edges of the elastic portion 130d. The straight portions 130ad are provided in parallel with the width direction so that the curved portions 130bd are more easily deformed by contact pressure.

The elastic portion 130d includes an upper elastic portion 131d connected to the first connection portion 110d and a lower elastic portion 133d connected to the second connection portion 120d.

A non-elastic portion 140d is formed between the upper elastic portion 131d and the lower elastic portion 133d. The non-elastic portion 140d is connected with the upper elastic portion 131d and the lower elastic portion 133d and is connected with a supporting portion 150d.

Before the metal molded product 100d tests a test object, the first connection portion 110d is in contact with a circuit wiring part, the upper elastic portion 131d can be compressively deformed in the longitudinal direction of the metal molded product 100d, and the second connection portion 120d is not in contact with the test object. Further, in the process in which the metal molded product 100d tests a test object, the second connection portion 120d comes into contact with the test object, so the lower elastic portion 133d can be compressively deformed.

An end of the first connection portion 110d is a free end and another end is connected to the upper elastic portion 131d, so it can be elastically vertically moved by contact pressure. An end of the second connection portion 120d is a free end and another end is connected to the lower elastic portion 133d, so it can be elastically vertically moved by contact pressure.

The upper elastic portion 131d requires a compression amount that enables the first connection portions 110d of a plurality of metal molded products 100d to stably come into contact with circuit wiring parts, respectively, whereas the lower elastic portion 133d requires a compression amount that enables the second connection portions 120d of a plurality of metal molded products 100d to stably come into contact with test objects, respectively. Accordingly, the spring coefficient of the upper elastic portion 131d and the spring coefficient of the lower elastic portion 133d are different from each other. For example, the length of the upper elastic portion 131d and the length of the lower elastic portion 133d are different from each other. Further, the length of the lower elastic portion 133d in the longitudinal direction may be made larger than the length of the upper elastic portion 131d in the longitudinal direction.

An end of the upper elastic portion 131d is connected to the first connection portion 110d and another end is connected to the non-elastic portion 140d. An end of the lower elastic portion 133d is connected to the second connection portion 120 and another end is connected to the non-elastic portion 140d. The elastic portion 130d connected with the non-elastic portion 140d is a curved portion 130bd of the elastic portion 130d. Accordingly, the upper elastic portion 131d and the lower elastic portion 133d maintain elasticity with respect to the non-elastic portion 140d.

The upper elastic portion 131d is disposed over the non-elastic portion 140d and the lower elastic portion 133d is disposed under the non-elastic portion 140d. By the non-elastic portion 140d, the region where the upper elastic portion 131d is provided and the region where the lower elastic portion 133d is provided are separated from each other. The upper elastic portion 131d and the lower elastic portion 133d are compressed or extended with the non-elastic portion 140d therebetween. By the configuration of the non-elastic portion 140d provided between the upper elastic portion 131d and the lower elastic portion 133d, even though the length of the metal molded product 100d is made larger, it is possible to ensure mechanical rigidity of the metal molded product 100d.

The non-elastic portion 140d includes a cavity 145d. The cavity 145d is formed through the non-elastic portion 140d in the thickness direction (±z direction). A plurality of cavities 145d may be provided to be spaced apart from each other. By the configuration of the cavity 145d, the surface area of the non-elastic portion 140d can be made large. Accordingly, it is possible to quickly dissipate heat generated at the non-elastic portion 140d, so it is possible to suppress an increase of temperature of the non-elastic portion 140d. A triangle is shown as an example of the shape of the cavity 145d, but the shape is not limited thereto.

The metal molded product 100d includes a supporting portion 150d disposed outside the elastic portion 130d in the longitudinal direction of the metal molded product 100d to prevent the elastic portion 130d from buckling by horizontally bending or curving when the elastic portion 130d is guided to be compressed or extended in the longitudinal direction of the metal molded product 100d.

The supporting portion 150d includes an upper supporting portion 151d disposed outside the upper elastic portion 131d and a lower supporting portion 153d disposed outside the lower elastic portion 133d.

In this configuration, the curved portions 130bd of the upper elastic portion 131d and the upper supporting portion 151d are spaced apart and opposite each other, and a gap is formed between the curved portions 130bd and the upper supporting portion 151d. The aspect ratio (H:d) of the total thickness dimension H and the distance d of gaps has a range of 13:1 or more and 80:1 or less. For example, the distance d of a gap may be 4 μm and the height H of a gap may be 100 μm . By increasing the aspect ratio of the gap space between the curved portions 130bd and the upper supporting portion 151d, it is possible to make the metal molded product 100d have a compact structure in the width direction (±x direction) while increasing the total thickness dimension H. Further, it is possible to prevent the upper elastic portion 131d from excessively tilting in the width direction (±x direction).

Further, the curved portions 130bd of the lower elastic portion 133d and the lower supporting portion 153d are spaced apart and opposite each other, and a gap is formed between the curved portions 130bd and the lower supporting portion 153d. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the gap space between the curved portions 130bd and the lower supporting portion 153d, it is possible to make the metal molded product 100d have a compact structure in the width direction (±x direction) while increasing the total thickness dimension H. Further, it is possible to prevent the lower elastic portion 133d from excessively tilting in the width direction (±x direction).

The first connection portion 110d forms an additional contact point between the first connection portion 110d and the upper supporting portion 151d while vertically moving downward into the upper supporting portion 151d. When the second connection portion 120d vertically moves upward in to the lower supporting portion 153d, a second contact point performs a wiping operation. When the metal molded product 100d test a test object, the metal molded product 100d maintains a vertical state and the second connection portion 120d maintains contact pressure with the test object and simultaneously performs a wiping operation on the test object while tilting.

The upper supporting portion 151d and the lower supporting portion 153d are formed in the longitudinal direction of the metal molded product 100d, and the upper supporting portion 151d and the lower supporting portion 153d are integrally connected to the non-elastic portion 140d. Further, the upper elastic portion 131d and the lower elastic portion 133d are integrally connected to the non-elastic portion 140d, whereby the metal molded product 100d is configured entirely as a single body.

A locking portion 152d is disposed on the outer wall of the upper supporting portion 151d so that the metal molded product 100d can be locked and fixed to a guide plate. That is, the upper supporting portion 151d includes a locking portion 152d protruding to prevent the metal molded product 100d from separating from a guide plate. The locking portion 152 may be configured to be locked to at least one of guide plates. Preferably, the locking portion 152d may be configured to be locked to an upper guide plate. In this case, the locking portion 152d includes an upper locking portion 152ad that is locked to a first surface of the upper guide plate and a lower locking portion 152bd that is locked to a second surface of the upper guide plate. The upper guide plate is locked between the upper locking portion 152ad and the lower locking portion 152bd, whereby the metal molded product 100d is not separated from the upper guide plate. Meanwhile, in contrast to this, the locking portion 152d may be composed of an upper locking portion 152ad that is locked to a first surface of a lower guide plate and a lower locking portion 152bd that is locked to a second surface of the lower guide plate.

The metal molded product 100d has intersections where two portions intersect in the x-y plane. The upper locking portion 152ad and the upper supporting portion 151d form an intersection where two portions intersect in the x-y plane. An intersection has an open hole. The radius r of open holes may have a range 1 μm or more and 3 μm or less. Based on the open hole with the smallest radius among the open holes, the aspect ratio (H:r) of the total thickness dimension H and the radius r of the open holes has a range of 40:1 or more and 60:1 or less. Accordingly, it is possible to enable the metal molded product 100d to come into close contact with the inner wall of a guide hole of a guide plate while minimizing a loss of the metal molded product 100d.

The upper supporting portion 151d includes a first upper supporting portion 151ad disposed at a side of the upper elastic portion 131d and a second upper supporting portion 151bd disposed at another side of the upper elastic portion 131d. The first upper supporting portion 151ad and the second upper supporting portion 151bd are close to each other and spaced apart from each other at both ends, thereby forming an upper opening 153ad.

The lower supporting portion 153d includes a first lower supporting portion 153ad disposed at a side of the lower elastic portion 133d and a second lower supporting portion 153bd disposed at another side of the lower elastic portion 133d. The first lower supporting portion 153ad and the second lower supporting portion 153bd are close to each other and spaced apart from each other at both ends, thereby forming a lower opening 153bd.

The upper opening 153ad and the lower opening 153bd perform a function of preventing the first and second connection portions 110d and 120d from excessively protruding outside the upper supporting portion 151d and the lower supporting portion 153d, respectively, due to the restoring force of the upper elastic portion 131d and the lower elastic portion 133d.

The first upper supporting portion 151ad has a first door portion 154ad extending toward the upper opening 153ad and the second upper supporting portion 151bd has a second door portion 154bd extending toward the upper opening 153ad. A space in which the first door portion 154ad and the second door portion 154bd are spaced apart and opposite each other is the upper opening 153ad. The open width of the upper opening 153ad is made smaller than the left-right length of the straight portions 130ad of the upper elastic portion 131d.

In this configuration, the first door portion 154ad and the first connection portion 110d are spaced apart and opposite each other and a gap is formed between the first door portion 154ad and the first connection portion 110d. Further, the second door portion 154bd and the first connection portion 110d are spaced apart and opposite each other and a gap is formed between the second door portion 154bd and the first connection portion 110d. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of the distance d of the gap between the first door portion 154ad and the first connection portion 110d and the distance d of the gap between the second door portion 154bd and the first connection portion 110d, it is possible to make the metal molded product 100d have a compact structure in the width direction (±x direction) while increasing the total thickness dimension H. Further, it is possible to prevent the first connection portion 110d from excessively tilting in the width direction (±x direction) when an eccentric pressing force is applied to the first connection portion 110d.

The first connection portion 110d is connected with the straight portions 130ad of the upper elastic portion 131d and has a rod shape elongated in the longitudinal direction of the metal molded product 100d. The first connection portion 110d can vertically pass through the upper opening 153ad formed by the first upper supporting portion 151ad and the second upper supporting portion 151bd. Further, since the left-right length of the straight portions 130ad of the upper elastic portion 131d is larger than the width of the upper opening 153ad, the straight portions 130ad of the upper elastic portion 131d cannot pass through the upper opening 153ad. Accordingly, an ascending stroke of the first connection portion 110d is restricted.

The upper supporting portion 151d and the lower supporting portion 153d are close to each other and spaced apart from each other at both ends, thereby forming the upper opening 153ad through which the first connection portion 110d can vertically pass. When the first connection portion 110d is vertically moved downward inside the upper supporting portion 151d, the open width of the upper opening 153ad decreases and the first connection portion 110d comes in contact with the upper supporting portion 151d, thereby forming an additional contact point.

The first upper supporting portion 151ad has a first extension 155ad extending to an inner space and the second upper supporting portion 151bd has a second extension 155bd extending to an inner space.

In more detail, the first extension 155ad is connected to the first door portion 154ad. An end of the first extension 155ad is connected to the first door portion 154ad and another end extends to the inner space of the upper supporting portion 151d and is configured as a free end. The second extension 155bd is connected to the second door portion 154bd. An end of the second extension 155bd is connect3ed to the second door portion 154bd and another end extends to the inner space of the upper supporting portion 150d and is configured as a free end.

The first connection portion 110d has a first protrusion 110ad extending toward the first extension 155ad and a second protrusion 110bd extending toward the second extension 155bd. When the first connection portion 110d is moved downward by a pressing force, the first protrusion 110ad and the second protrusion 110bd can come into contact with the first extension 155ad and the second extension 155bd, respectively.

When the first connection portion 110d is moved downward, the first protrusion 110ad and the second protrusion 110bd can come into contact with the first extension 155ad and the second extension 155bd, respectively, thereby forming additional contact points.

The first extension 155ad and the second extension 155bd are inclined, so when the first connection portion 110d is vertically moved downward, the first protrusion 110ad and the second protrusion 110bd press the first extension 155ad and the second extension 155bd, respectively, whereby the gap space between the first door portion 154ad and the second door portion 154bd decreases. In other words, the more the first connection portion 110d is moved downward, the more the first door portion 154ad and the second door portion 154bd are deformed to approach to each other, thereby decreasing the open width of the upper opening 153ad. As described above, when the first connection portion 110d is vertically moved downward inside the upper supporting portion 151d, the open width of the upper opening 153ad decreases and the first connection portion 110d comes into contact with the upper supporting portion 151d, thereby forming an additional contact point.

When the first connection portion 110d is moved downward, primarily, the first and second protrusions 110ad and 110bd and the first and second extensions 155ad and 155bd form additional contact points by coming into contact with each other, and secondarily, the first and second door portions 154ad and 154bd and the first connection portion 110d form additional contact points by coming into contact with each other. As described above, as the first connection portion 110d is vertically moved downward, an additional current path is formed between the first connection portion 110d and the upper supporting portion 151d. The additional current path is formed directly from the upper supporting portion 151d to the first connection portion 110d not through the elastic portion 130d. Since the additional current path is formed, more stable electrical connection becomes possible.

The open width of the upper opening 153ad decreases in proportion to the vertical descending distance of the first connection portion 110d. Further, when downward pressure is applied to the first connection portion 110d even after the first and second door portions 154ad and 154bd come into contact with the first connection portion 110d, the friction force between the first and second door portions 154ad and 154bd and the first connection portion 110d further increases. The increased friction force prevents excessive descending of the first connection portion 110d. Accordingly, it is possible to prevent the elastic portion (in more detail, the upper elastic portion 131d) from being excessively compressively deformed.

The second connection portion 120d is connected at the upper portion to the lower elastic portion 133d and the end thereof passes through the lower opening 153bd.

The second connection portion 120d includes an inner body 121d connected with the lower elastic portion 133d, an extension body 123d protruding outside the lower supporting portion 153d, and a protrusion 188d formed at the end of the extension body 123d.

The second connection portion 120d is repeatedly moved upward and downward, and the left-right length of the bottom surface of the inner body 121d is made larger than the open width of the lower opening 153bd so that the inner body 121d is not separated from the supporting portion 150d.

A cavity 122d is formed at the inner body 121. The cavity 122d is formed through the inner body 121d in the thickness direction (±z direction). By the configuration of the cavity 122d, the inner body 121d can be compressively deformed by a pressing force, and as the inner body 121d is compressively deformed, the wiping operation of the protrusion 188d is more smoothly performed.

The extension body 123d extends from the inner body 121d and at least a portion thereof is positioned outside the lower supporting portion 153d through the lower opening 153bd.

The protrusion 188d is formed at the end of the extension body 123d. The protrusion 188d is formed with a thickness smaller than the thickness of the extension body 123d.

In this configuration, the second connection portion 120d and the lower supporting portion 153d are spaced apart and opposite each other and a gap is formed between the second connection portion 120d and the lower supporting portion 153d. The aspect ratio (H:d) of the total thickness dimension H and the distance d of gaps has a range of 13:1 or more and 80:1 or less. For example, the distance d of a gap may be 4 μm and the height H of a gap may be 100 μm. By increasing the aspect ratio of distance d of the gap between the second connection portion 120d and the lower supporting portion 153d, it is possible to make the metal molded product 100d have a compact structure in the width direction (±x direction) while increasing the total thickness dimension H. Further, it is possible to prevent the second connection portion 120d from excessively tilting in the width direction (±x direction) when an eccentric pressing force is applied to the second connection portion 120d.

Meanwhile, any one of (i) the gap between the curved portions 130bd of the upper elastic portion 131d and the upper supporting portion 151d, (ii) the gap between the curved portions 130bd of the lower elastic portion 133d and the lower supporting portion 153d, (iii) the gap between the first door portion 154ad and the first connection portion 110d, (iv) the gap between the second door portion 154bd and the first connection portion 110d, and (v) the gap between the second connection portion 120d and the lower supporting portion 153d may be the smallest gap.

In the process of wiping operation of the protrusion 188d, fragments of the oxide film layer formed on the surface of a test object are generated. The fragments tend to continuously grow while they clump together through mutual adhesion. However, the fragments are caught at the end of the extension body 123d, which is the base of the protrusion 188d, so they are guided to naturally fall without further growth. By the configuration of the protrusion 188d formed with a thickness smaller than the extension body 123d at the end of the extension body 123d, as described above, continuous growth of the fragments of an oxide film layer generated in the process of wiping is prevented.

The metal molded products 100a to 100d according to preferred embodiments of the present disclosure described above may be electroconductive contact pins. Electroconductive contact pins are mounted on testing apparatuses and used to transmit electrical signals in electrical and physical contact with test objects. Test apparatuses includes an electroconductive contact pin installed in a guide plate by being inserted in a guide hole of at least one guide plate. The testing apparatuses may be testing apparatuses that are used in the manufacturing process of semiconductors, and for example, may be a probe card or a test socket. Electroconductive contact pins may be electroconductive contact pins are provided on a probe card and test semiconductor chips or may be socket pins provided on a test socket for testing packaged semiconductor packages and testing semiconductor packages. Testing apparatuses in which electroconductive contact pin according to a preferred embodiment of the present disclosure can be used are not limited thereto and include any kinds of testing apparatus as long as they are used to check whether test objects are defective by applying electricity. Test objects of testing apparatuses may include a semiconductor device, a memory chip, a microprocessor chip, a logic chip, a light emitting device, or combinations thereof. For example, a test object includes a logic LSI (such as an ASIC, an FPGA, and an ASSP) a microprocessor (such as a CPU and a GPU), a memory (a DRAM, a Hybrid Memory Cube (HMC), a Magnetic RAM (MRAM), a Phase-Change Memory (PCM), a Resistive RAM (ReRAM), Ferroelectric RAM (FeRAM), and a NAND flash), a semiconductor light emitting device (including an LED, a mini LED, a micro LED, etc.), a power device, an analog IC (such as a DC-AC converter and an Insulated Gate Bipolar Transistor (IGBT)), MEMS (such as an accelerometer, a pressure sensor, a vibrator, and a gyroscope sensor), a wire-free device (such as GPS, FM, NFC, RFEM, MMIC, and WLAN), a discrete device, BSI, CIS, a camera module, CMOS, a passive device, a GAW filter, an RF filter, RF IPD, APE, and BB.

Although the present disclosure was described above through preferred embodiments, those skilled in the art may change or modify the present disclosure in various ways within a range not departing from the characteristics of the present disclosure described in the following claims.

### DESCRIPTION OF REFERENCE NUMERALS

100a, 100b 100c , 100d: metal molded product
d: distance of gap
t: distance of line width
r: radius of open hole

1. A metal molded product manufactured using a mold made of an anodized film material, wherein
the metal molded product has a total length dimension (L) in a longitudinal direction (=y direction), has a total thickness dimension (H) in a thickness direction (=z direction) perpendicular to the longitudinal direction, and has a total width dimension (W) in a width direction (±x direction) perpendicular to the longitudinal direction,
a gap is formed between two portions spaced apart and opposite each other, and,
based on a gap with a smallest distance among the gaps, an aspect ratio (H:d) of the total thickness dimension (H) and a distance (d) of the gaps has a range of 13:1 or more and 80:1 or less.

2. A metal molded product manufactured using a mold made of an anodized film material, wherein
the metal molded product has a total length dimension (L) in a longitudinal direction (±y direction), has a total thickness dimension (H) in a thickness direction (=z direction) perpendicular to the longitudinal direction, and has a total width dimension (W) in a width direction (±x direction) perpendicular to the longitudinal direction,
the metal molded product has line widths, and,
based on a smallest line width among the line widths, an aspect ratio (H:t) of the total thickness dimension (H) and a distance (t) of the line widths has a range of 13:1 or more and 80:1 or less.

3. A metal molded product manufactured using a mold made of an anodized film material, wherein
the metal molded product has a total length dimension (L) in a longitudinal direction (±y direction), has a total thickness dimension (H) in a thickness direction (=z direction) perpendicular to the longitudinal direction, and has a total width dimension (W) in a width direction (±x direction) perpendicular to the longitudinal direction,
the metal molded product has intersections where two portions intersect in an x-y plane,
the interest has an open hole, and,
based on an open hole with a smallest radius among the open holes, an aspect ratio (H:r) of the total thickness dimension (H) and a radius (r) of the open holes has a range of 26:1 or more and 160:1 or less.

4. The metal molded product of claim 1, wherein the total thickness dimension is 80 μm or more and 160 μm or less.

5. The metal molded product of claim 1, wherein the distance of the gap with the smallest distance among the gaps is 2 μm or more and 6 μm or less.

6. The metal molded product of claim 2, wherein a distance of the line width with the smallest distance among the line widths is 2 μm or more and 6 μm or less.

7. The metal molded product of claim 3, wherein the radius of the open hole with the smallest radius among the open holes is 1 μm or more and 3 μm or less.

8. The metal molded product of claim 1, wherein any one of the two portions spaced apart and opposite each other is a portion that slides in one direction.

9. The metal molded product of claim 1, wherein the metal molded product comprises
a supporting frame, and
a body being separable from the supporting frame, and
a distance of a line width of a cutting portion at which the supporting frame and the body are connected is 2 μm or more and 6 μm or less.

10. The metal molded product of claim 1, wherein the metal molded product has a plurality of metal layers stacked in the thickness direction of the metal molded product.

11. The metal molded product of claim 1, wherein the metal molded product is an electroconductive pin provided between a test object and a circuit board.
